(19) United States
(12) Patent Application Publication
(10) Pub. No.: US 2026/0106431 A1
(43) Pub. Date: Apr. 16, 2026

(54) LIGHT EMITTING DEVICE AND LIGHT EMITTING MODULE

(71) Applicants: NICHIA CORPORATION, Anan-shi, Tokushima (JP); FURUKAWA ELECTRIC CO., LTD., Tokyo (JP)

(72) Inventor: Toshiaki YAMASHITA, Komatsushima-shi (JP)

(73) Assignees: NICHIA CORPORATION, Anan-shi, Tokushima (JP); FURUKAWA ELECTRIC CO., LTD., Tokyo (JP)

(21) Appl. No.: 19/115,956

(22) PCT Filed: Sep. 20, 2023
(86) PCT No.: PCT/JP2023/034145

§ 371 Date: Mar. 27, 2025

(30) Foreign Application Priority Data
Sep. 29, 2022 (JP) 2022-155944

(51) Int. Cl. H01S 5/02255; H01S 5/02208; H01S 5/02253; H01S 5/02315

(52) U.S. Cl. CPC H01S 5/02255; H01S 5/02208; H01S 5/02253; H01S 5/02315

(57) ABSTRACT

A light-emitting device includes: a base having a mounting surface; a plurality of semiconductor laser elements each configured to emit a laser beam from a light emission surface in a first direction, which are arranged on the mounting surface in a second direction; a plurality of first mirror members each having a first reflective surface configured to reflect the laser beam emitted from a corresponding one of the plurality of semiconductor laser elements to change a travel direction of the laser beam into a direction away from the mounting surface; a cover configured to transmit the laser beams reflected by the first reflective surfaces; and at least one second mirror member arranged on an upper surface of the cover, and having a second reflective surface configured to reflect the laser beams transmitted through the cover to further change the travel directions of the laser beams.

### CROSS-REFERENCE TO RELATED APPLICATIONS

The present application is a national stage of PCT Application No. PCT/JP2023/034145, filed on Sep. 20, 2023, which claims priority to Japanese Patent Application No. 2022-155944, filed on Sep. 29, 2022.

### TECHNICAL FIELD

The present disclosure relates to light-emitting devices and light-emitting modules.

### BACKGROUND

A technique for increasing the power of laser light by combining a plurality of laser beams emitted from a plurality of semiconductor laser elements has in recent years been developed. Japanese Patent Publication No. 2018-530768 discloses an example laser system capable of implementing such high-power laser light.

### SUMMARY

There has been a demand for a light-emitting device that includes a plurality of semiconductor laser elements, and that effectively dissipates, out of the light-emitting device, heat generated by the plurality of semiconductor laser elements during driving.

A light-emitting device according to one embodiment of the present disclosure includes: a base having a mounting surface; a plurality of semiconductor laser elements each having a light emission surface from which a laser beam is emitted in a first direction, the plurality of semiconductor laser elements arranged on the mounting surface in a second direction intersecting the first direction; a plurality of first mirror members each having a first reflective surface configured to reflect the laser beam emitted from a corresponding one of the plurality of semiconductor laser elements to change the travel direction of the laser beam into a direction away from the mounting surface; a cover having a counter surface facing the mounting surface and an upper surface on a side opposite to the counter surface, the cover positioned above the plurality of semiconductor laser elements and the plurality of first mirror members, the cover configured to transmit the laser beams reflected by the first reflective surfaces; and at least one second mirror member arranged on the upper surface of the cover, and having a second reflective surface configured to reflect the laser beams transmitted through the cover to further change the travel directions of the laser beams. The plurality of first mirror members are arranged on the mounting surface such that positions in the first direction of the first reflective surfaces are different from each other. With the the mounting surface serving as a reference plane, heights, from the reference plane, of the optical axes of the laser beams reflected by the second reflective surface are different from each other.

A light-emitting module according to one embodiment of the present disclosure includes: the light-emitting device; a plurality of fifth mirror members each having a fifth reflective surface configured to reflect, in a third direction, the laser beam emitted from a corresponding one of the semiconductor laser elements and reflected by the first reflective surface and the second reflective surface sequentially in this order; and a condensing lens configured to couple, to an optical fiber, a plurality of laser beams that have been emitted from the plurality of semiconductor laser elements and then reflected by the first reflective surface, the second reflective surface, and the fifth reflective surface sequentially in this order.

Another light-emitting device according to one embodiment of the present disclosure includes: a base having a mounting surface; a plurality of first semiconductor laser elements each having a first light emission surface from which a first laser beam is emitted in a first direction, the plurality of first semiconductor laser elements arranged on the mounting surface in a second direction intersecting the first direction; a plurality of second semiconductor laser elements each having a second light emission surface from which a second laser beam is emitted in the first direction, and arranged on the mounting surface in the second direction; a plurality of first mirror members each having a first reflective surface configured to reflect the first laser beam emitted from a corresponding one of the plurality of first semiconductor laser elements to change the travel direction of the first laser beam into a direction away from the mounting surface; a plurality of third mirror members each having a third reflective surface configured to reflect the second laser beam emitted from a corresponding one of the plurality of second semiconductor laser elements to change the travel direction of the second laser beam into a direction away from the mounting surface; a cover having a counter surface facing the mounting surface and an upper surface on a side opposite to the counter surface, the cover positioned above the plurality of first semiconductor laser elements, the plurality of first mirror members, the plurality of second semiconductor laser elements, and the plurality of third mirror members, the cover configured to transmit the first laser beams reflected by the first reflective surfaces and the second laser beams reflected by the third reflective surfaces; a second mirror member arranged on the upper surface of the cover, and having a second reflective surface configured to reflect the first laser beams transmitted through the cover to further change the travel directions of the first laser beams; and a fourth mirror member arranged on the upper surface of the cover, at a location further in a direction opposite to the first direction than the second mirror member, the fourth mirror member having a fourth reflective surface configured to reflect the second laser beams transmitted through the cover to further change the travel directions of the second laser beams. The plurality of second semiconductor laser elements are arranged at a location further in the direction opposite to the first direction than the plurality of first semiconductor laser elements. The plurality of first mirror members are arranged on the mounting surface such that positions in the first direction of the first reflective surfaces are different from each other. The plurality of third mirror members are arranged on the mounting surface such that positions in the first direction of the third reflective surfaces are different from each other. The plurality of third mirror members are arranged at locations further in the direction opposite to the first direction than the plurality of first mirror members.

Another light-emitting module according to one embodiment of the present disclosure includes: the another light-emitting device; a plurality of fifth mirror members each having a fifth reflective surface configured to reflect, in a third direction, the first laser beam emitted from a corresponding one of the first semiconductor laser elements and reflected by the first reflective surface and the second reflective surface sequentially in this order; a plurality of sixth mirror members each having a sixth reflective surface configured to reflect, in the third direction, the second laser beam emitted from a corresponding one of the second semiconductor laser elements and reflected by the third reflective surface and the fourth reflective surface sequentially in this order; and a condensing lens configured to couple, to an optical fiber, a plurality of first laser beams that have been emitted from the plurality of first semiconductor laser elements and then reflected by the first reflective surface, the second reflective surface, and the fifth reflective surface sequentially in this order, and a plurality of second laser beams that have been emitted from the plurality of second semiconductor laser elements and then reflected by the third reflective surface, the fourth reflective surface, and the sixth reflective surface sequentially in this order.

According to embodiments of the present disclosure, a light-emitting device including a plurality of semiconductor laser elements can effectively dissipates heat generated by the plurality of semiconductor laser elements during driving out of the light-emitting device.

### BRIEF DESCRIPTION OF THE DRAWINGS

FIG. 1A is a perspective view schematically illustrating an example configuration of a light-emitting device according to a first embodiment of the present disclosure.

FIG. 1B is an exploded perspective view of the light-emitting device of FIG. 1A.

FIG. 1C is a top view of a configuration of the light-emitting device of FIG. 1A with a cover, a second mirror member and a slow-axis collimating lens array removed.

FIG. 1D is a cross-sectional view of the light-emitting device of FIG. 1A taken parallel to a YZ plane.

FIG. 2A is a perspective view schematically illustrating Variation 1 of the light-emitting device according to the first embodiment of the present disclosure.

FIG. 2B is an exploded perspective view schematically illustrating a configuration of Variation 2 of the light-emitting device according to the first embodiment of the present disclosure.

FIG. 3A is a top view schematically illustrating an example configuration of a light-emitting module according to the first embodiment of the present disclosure.

FIG. 3B is a side view schematically illustrating an example configuration of the light-emitting module according to the first embodiment of the present disclosure.

FIG. 3C is another side view schematically illustrating an example configuration of the light-emitting module according to the first embodiment of the present disclosure.

FIG. 4A is a perspective view schematically illustrating an example configuration of a light-emitting device according to a second embodiment of the present disclosure.

FIG. 4B is an exploded perspective view of the light-emitting device of FIG. 4A.

FIG. 4C is a top view of the light-emitting device of FIG. 4B with a cover and components on the cover removed.

FIG. 4D is a cross-sectional view of the light-emitting device of FIG. 4A taken parallel to the YZ plane.

FIG. 5A is a top view schematically illustrating an example configuration of a light-emitting module according to a second embodiment of the present disclosure.

FIG. 5B is a side view schematically illustrating an example configuration of the light-emitting module according to the second embodiment of the present disclosure.

FIG. 5C is another side view schematically illustrating an example configuration of the light-emitting module according to the second embodiment of the present disclosure.

FIG. 6A is an exploded perspective view of a laser light source.

FIG. 6B is a cross-sectional view of a laser light source taken parallel to a YZ plane.

### DETAILED DESCRIPTION

A light-emitting device and a light-emitting module according to an embodiment of the present disclosure will be described below with reference to the accompanying drawings. The light-emitting module includes a plurality of light-emitting devices. The same reference signs shown in multiple drawings refer to the same or similar parts.

The embodiment described below is exemplified to embody a technical idea of the present invention, and the present invention is not limited to the following. Furthermore, the descriptions of sizes, materials, shapes, relative arrangements, and the like of components are not intended to limit the scope of the present invention thereto but intended to be illustrative. The size and positional relationship of members illustrated in the drawings may be exaggerated to facilitate understanding.

In this description and the accompanying claims, the terms referring to polygons, such as triangles and quadrangles, encompass polygonal shapes with modified corners (ends of sides), such as rounded, slanted, chamfered, or beveled corners, and in addition, polygonal shapes in which intermediate portion of sides are modified. That is, any polygon-based shapes with partial modification are construed as a “polygon”recited in the description and claims.

### First Embodiment

### Light-Emitting Device

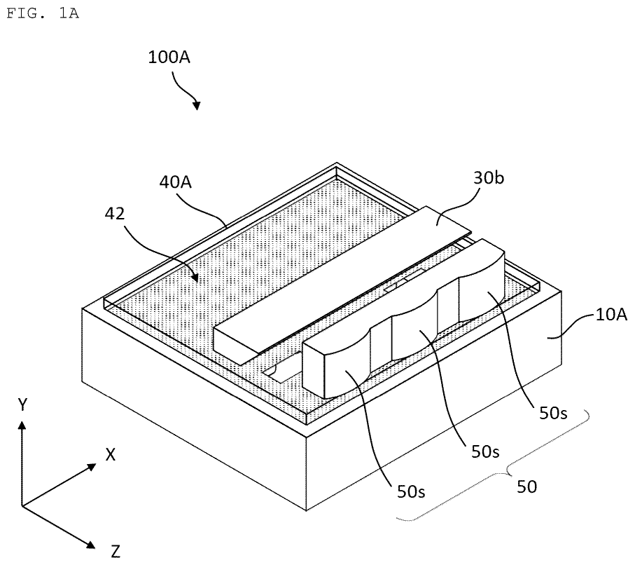

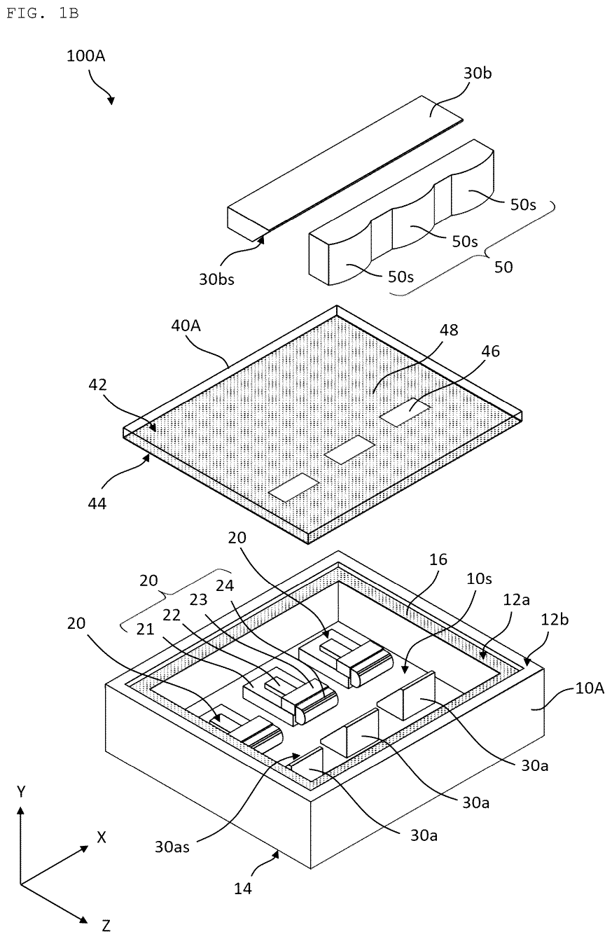

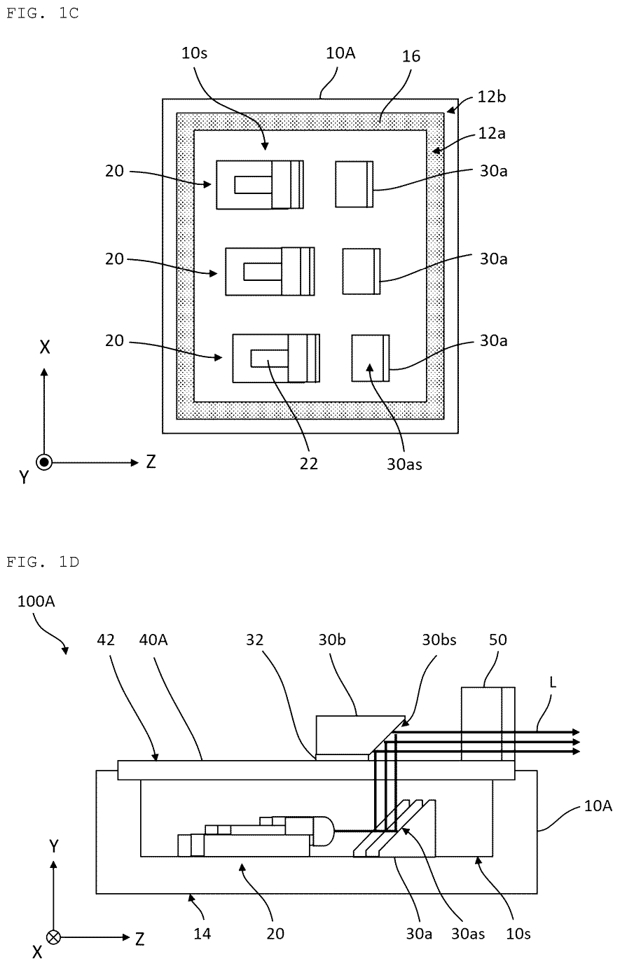

First, an example configuration of a light-emitting device according to a first embodiment of the present disclosure will be described with reference to FIGS. 1A to 1D. FIG. 1A is a perspective view schematically illustrating an example configuration of the light-emitting device according to the first embodiment of the present disclosure. The light-emitting device 100A of FIG. 1A can be, for example, arranged on a placement surface of a support base body. The support base body is described in detail in the description of the light-emitting module according to the first embodiment below. FIG. 1B is an exploded perspective view of the light-emitting device of FIG. 1A. The light-emitting device 100A of FIG. 1B includes a base 10A, a plurality of laser light sources 20, a plurality of first mirror members 30a, a second mirror member 30b, a cover 40A and a slow-axis collimating lens array 50. The slow-axis collimating lens array 50 is formed in a monolithic body, and includes a plurality of slow-axis collimating lenses 50s, each of which individually functions as a lens.

The base 10A has a mounting surface 10s. Each first mirror member 30a has a first reflective surface 30as, and the second mirror member 30b has a second reflective surface 30bs. The cover 40A has an upper surface 42 and a lower surface 44. The laser light source 20 is a chip-on-submount type semiconductor laser light source including a semiconductor laser element. The number of laser light sources 20 is three in the example of FIG. 1B, but is not limited thereto. The number of laser light sources 20 may be two, or four or more. The number of first mirror members 30a and the number of slow-axis collimating lenses 50s are preferably the same as the number of laser light sources 20. The light-emitting device 100A may further include a protective element such as a Zener diode and/or a temperature measurement element for measuring internal temperature such as a thermistor.

These drawings schematically illustrate an X-axis, a Y-axis and a Z-axis that are orthogonal to one another for reference. The direction of an arrow on the X-axis is referred to as a +X direction, and an opposite direction thereof is referred to as a −X direction. When the ±X directions are not distinguished from each other, the ±X directions are simply referred to as an X direction. The same applies to a Y direction and a Z direction. For ease of description, in the present description, the +Y direction is referred to as “upward,” and the −Y direction is referred to as “downward.” This does not limit the orientation of the light-emitting device during use, and the orientation of the light-emitting device may be any chosen orientation.

FIG. 1C is a top view of a configuration of the light-emitting device 100A of FIG. 1A from which the cover 40A, the second mirror member 30b and the slow-axis collimating lens array 50 are omitted. FIG. 1D is a cross-sectional view of the light-emitting device 100A of FIG. 1A taken parallel to the YZ plane.

As will be described below in detail, in the light-emitting device 100A according to the first embodiment, as illustrated in FIG. 1D, the plurality of laser light sources 20 and the plurality of first mirror members 30a are arranged on the mounting surface 10s, and a laser beam L emitted from each of the plurality of laser light sources 20 is reflected by the first reflective surface 30as and the second reflective surface 30bs sequentially in this order and travels in the +Z direction. As illustrated in FIG. 1C, the plurality of first mirror members 30a are arranged on the mounting surface 10s such that the positions in the Z direction of the first reflective surfaces 30as are different from each other. Therefore, even in the case in which the mounting surface 10s, on which the plurality of laser light sources 20 are mounted, extends in a single plane, the optical axes of the plurality of laser beams L can have different heights with respect to the mounting surface 10s as a height reference plane. This is because the distance between a point where the optical axis of the laser beam L meets the first reflective surface 30as and a point where the optical axis of the laser beam L meets the second reflective surface 30bs depends on the position in the Z direction of the first reflective surface 30as. The laser beam L emitted from the laser light source 20 is a beam collimated on a YZ plane, and the optical axis thereof passes through the center of the beam cross-section.

Furthermore, with the plurality of first mirror members 30a arranged on the mounting surface such that the positions of the first reflective surfaces 30as in the first direction are different from each other, a plurality of collimated light beams propagating at different heights can be obtained, so that the mounting surface 10s can extend in a single plane. Allowing a plurality of collimated light beams to propagate at different heights without providing height differences to the mounting surface 10s allows for reducing variations in the difference between the mounting surface 10s and a lower surface 14, which will be described below. Accordingly, variations in the amount of heat that is generated by the plurality of laser light sources 20 during driving and transmitted to the placement surface of the support base body can be reduced. Therefore, heat generated by the plurality of laser light sources 20 during driving can be effectively dissipated out of the light-emitting device 100A. For example, in the case in which the support base body includes a flow path that is positioned therein below the placement surface and extends in the X direction, variations in the degree of cooling of the plurality of laser light sources 20 in the light-emitting device 100A can be reduced by causing a liquid to flow in the flow path. In addition, in the case in which the support base body includes a heat sink below the placement surface, variations in the degree of heat dissipation of the plurality of laser light sources 20 in the light-emitting device 100A can be reduced. When the distance between the mounting surface 10s and the lower surface 14 immediately below the plurality of laser light sources 20 is uniform, variations in heat dissipation can be further reduced, resulting in effective heat dissipation.

Each component of the light-emitting device 100A will be described below.

### Base 10A

As illustrated in FIG. 1B, the base 10A includes a flat plate portion having the mounting surface 10s, on which the plurality of laser light sources 20 and the plurality of first mirror members 30a are mounted, and a lateral wall portion that is positioned around the mounting surface 10s, and surrounds the plurality of laser light sources 20 and the plurality of first mirror members 30a. The base 10A houses the plurality of laser light sources 20 and the plurality of first mirror members 30a. In the example of FIG. 1B, the mounting surface 10s is parallel to the XZ plane. The planar portion and the lateral wall portion may be monolithically formed or may be bonded together after being separately formed. In the example of FIG. 1B, the flat plate portion has, but is not limited to, a rectangular, flat plate shape. The planar portion may, for example, have a polygonal, circular, or elliptical, flat plate shape. The base 10A has a substantially box shape that is open on the top side.

The base 10A has a first upper surface 12a and a second upper surface 12b, which correspond to the upper surface of the lateral wall portion. The first upper surface 12a and the second upper surface 12b surround the plurality of laser light sources 20 and the plurality of first mirror members 30a as viewed from above in a direction normal to the mounting surface 10s. The second upper surface 12b is positioned above the first upper surface 12a, and surrounds the first upper surface 12a as viewed from above. The base 10A further has the lower surface 14, which corresponds to the lower surface of the planar portion. A direction normal to the mounting surfaces 10s is the +Y direction. In the present specification, the term “direction normal to a surface” refers to a direction that is perpendicular to the surface and is away from an object having the surface.

The first upper surface 12a of the base 10A is bonded to a peripheral region of the lower surface 44 of the cover 40A. A metal film 16 is provided on the first upper surface 12a. The base 10A and the cover 40A are bonded together by, for example, an inorganic bonding member provided on the metal film 16. The metal film 16 may, for example, be formed of at least one metal material selected from the group consisting of Ag, Cu, W, Au, Ni, Pt, Sn, Ti and Pd.

The base 10A has internal wiring for supplying power to each laser light source 20. Each laser light source 20 is electrically connected to an external circuit through the internal wiring, and the external circuit supplies power to the plurality of laser light sources 20 simultaneously or at different timings.

The base 10A includes a region formed of a material having a high thermal conductivity. The thermal conductivity of the material may, for example, be 10 W/m·K to 2000 W/m·K. With the base 10A having such a high thermal conductivity, heat generated by the laser light sources 20 during driving can be effectively transmitted to the support base body through the base 10A. The base 10A may, for example, formed of a ceramic selected from the group consisting of AlN, SiN, SiC and alumina. A size in the X direction of the base 10A may, for example, 7 mm to 45 mm; in the Y direction, 2 mm to 3 mm; and in the Z direction, 15 mm to 25 mm.

### Laser Light Sources 20

As illustrated in FIG. 1B, the plurality of laser light sources 20 are arranged on the mounting surface 10s. As illustrated in FIG. 1C, the plurality of laser light sources 20 are arranged in the X direction such that their positions in the Z direction are different from each other. In the example of FIG. 1C, the plurality of laser light sources 20 are arranged along the X direction so as to be gradually shifted in the −Z direction. The plurality of laser light sources 20 may be shifted in the +Z direction, which is opposite to the −Z direction, rather than the −Z direction. Alternatively, the positions in the Z direction of the plurality of laser light sources 20, which are arranged in the X direction, may be irregular.

In the case in which the mounting surface 10s extends in a single plane, variations in the amount of heat generated by the plurality of laser light sources 20 during driving and transmitted to the placement surface of the support base body can be reduced. Therefore, heat generated by the plurality of laser light sources 20 during driving can be effectively transmitted to the outside of the light-emitting device 100A.

As illustrated in FIG. 1B, each laser light source 20 includes a submount 21, an edge-emission type semiconductor laser element 22 supported by the submount 21, a lens support member 23, and a fast-axis collimating lens 24. The semiconductor laser element 22 is supported by the mounting surface 10s with the submount 21 located therebetween. The semiconductor laser element 22 is arranged so as to emit a laser beam toward the first reflective surface 30as. The lens support member 23 has a shape straddling the semiconductor laser element 22. The fast-axis collimating lens 24 is supported by an end surface of the lens support member 23.

The components of the laser light source 20 may be considered as components of the light-emitting device 100. Specifically, the light-emitting device 100A includes a plurality of submounts 21, a plurality of semiconductor laser elements 22, a plurality of lens support members 23 and a plurality of fast-axis collimating lenses 24. These components are positioned between the mounting surface 10s of the base 10A and the lower surface 44 of the cover 40A. The plurality of semiconductor laser elements 22 are arranged in the X direction indirectly on the mounting surface 10s. More specifically, each semiconductor laser element 22 is arranged on the mounting surface 10s with a corresponding submount 21 located therebetween. The plurality of semiconductor laser elements 22 may be arranged in the X direction directly on the mounting surface 10s.

The semiconductor laser element 22 has a light emission surface. The laser beam L is emitted from the light emission surface in the +Z direction. In the case in which the end surface extends in the X direction and is parallel to the XY plane, the laser beam L emitted from the semiconductor laser element 22 in the +Z direction diverges relatively quickly in the YZ plane, and relatively slowly in the XZ plane. The fast-axis direction of the laser beam L is parallel to the Y direction, and the slow-axis direction of the laser beam L is parallel to the X direction.

The laser beam L emitted from the semiconductor laser element 22 and then transmitted through the fast-axis collimating lens 24 is emitted from the laser light source 20. The fast-axis collimating lens 24 collimates the laser beam L emitted from the semiconductor laser element 22 in the YZ plane, more specifically in the fast-axis direction in the YZ plane. Therefore, the laser beam L emitted from the laser light source 20 is collimated in the YZ plane, and is not collimated in the XZ plane. As used herein, “collimate” encompasses not only causing the laser beam L to have parallel rays, but also reducing the spread angle of the laser beam L. The laser beams L emitted from the plurality of laser light sources 20 may have either the same wavelengths or different wavelengths. Alternatively, the wavelength of the laser beams L emitted from some of the laser light sources 20 may be different from that of the laser beams L emitted from the other laser light sources 20. A specific configuration of the laser light source 20 is described below.

As illustrated in FIG. 1D, the laser light source 20 is sealed by the base 10A and the cover 40A. This sealing is preferably hermetic. The hermetic sealing allows a reduction in dust deposited on the light emission surface of the semiconductor laser element 22, leading to a reduction in failure of the semiconductor laser element 22. The effect of the hermetic sealing increases as the wavelength of laser light emitted from the semiconductor laser element 22 decreases. This is because, with a configuration in which the light emission surface of the semiconductor laser element 22 is not hermetically sealed and is exposed to the outside air, the shorter the wavelength of the laser light, the more likely deterioration of the light emission surface due to dust attraction is to proceed during operation.

It should be noted that instead of the edge-emission type semiconductor laser element 22, a surface-emission type semiconductor laser element, such as a vertical-cavity surface-emitting laser (VCSEL) element, may be used. The surface-emission type semiconductor laser element is arranged such that a laser beam emitted from the semiconductor laser element travels in the +Z direction.

### First Mirror Member 30a and Second Mirror Member 30b

As illustrated in FIG. 1B, the plurality of first mirror members 30a are arranged on the mounting surface 10s of the base 10A. As illustrated in FIG. 1C, the plurality 41 first mirror members 30a are arranged in the X direction such that their positions in the Z direction of the first reflective surfaces 30as are different from each other. In the example of FIG. 1C, as with the plurality of laser light sources 20, the plurality of first mirror members 30a are arranged so as to be shifted in the −Z direction gradually along the X direction. The plurality of first mirror members 30a may be shifted in the +Z direction, which is opposite to the −Z direction, rather than the −Z direction. Alternatively, the positions in the Z direction of the plurality of first mirror members 30a, which are arranged in the X direction, may be irregular.

In the example of FIG. 1C, a plurality of distances, each defined as a distance between a respective one of the plurality of first mirror members 30a and a corresponding one of the plurality of laser light sources 20, are substantially the same. The distance is between a position where the optical axis of the laser beam L meets the first reflective surface 30as of each first mirror member 30a, and the center of the light emission surface of the semiconductor laser element 22 included in a corresponding laser light source 20. With such a configuration, all laser beams reflected by the first mirror members 30a and the second mirror members 30b have equal beam diameters, which facilitates downstream optical design.

The first mirror member 30a has a uniform cross-sectional shape in the X direction. The cross-sectional shape is a substantially triangular shape. The first mirror member 30a has a bottom surface, a back surface and an inclined surface connecting the bottom surface and the back surface. The bottom surface is parallel to the XZ plane, and the back surface is parallel to the XY plane. The normal direction of the inclined surface is parallel to the YZ plane, forms an acute angle with the +Y direction, and forms an acute angle with the −Z direction. In the present specification, an angle formed between two directions has a positive value and does not have a negative value. An angle formed between the bottom surface and the inclined surface of the first mirror member 30a is 45° in the example of FIG. 1D, but is not limited thereto, and may be, for example, in the range of 30° to 60°.

The first mirror member 30a has the first reflective surface 30as. The first reflective surface 30as is inclined with respect to the mounting surface 10s of the base 10A and faces obliquely upward. As used herein, “obliquely upward” means a direction forming an angle in the range of 30° to 60° with the +Y direction.

As illustrated FIG. 1D, each first mirror member 30a, more specifically the first reflective surface 30as thereof, reflects the laser beam L emitted from the corresponding laser light source 20 to change the travel direction of the laser beam L into a direction away from the mounting surface 10s of the base 10A. An angle formed between the direction in which the laser beam L travels away from the mounting surface 10s of the base 10A and the direction normal to the mounting surface 10s may, for example, be in the range of 0° to 5°.

As illustrated in FIG. 1A, the second mirror member 30b is arranged on an upper surface 42 of the cover 40A. The second mirror member 30b has a shape extending in the X direction. The second mirror member 30b also has a uniform cross-sectional shape in the X direction. The cross-sectional shape is substantially trapezoidal. The second mirror member 30b has an upper surface, a lower surface, a back surface, and an inclined surface connecting the upper surface and the lower surface. Each of the upper and lower surfaces is parallel to the XZ plane. A size in the X direction of the lower surface is equal to a size in the X direction of the upper surface. Meanwhile, a size in the Z direction of the lower surface is smaller than that of the upper surface. The direction normal to the inclined surface is parallel to the YZ plane, forms an acute angle with the −Y direction, and forms an acute angle with the +Z direction. An angle formed between the upper surface and the inclined surface of the second mirror member 30b is, 45° in the example of FIG. 1D, but is not limited thereto, and may, for example, be in the range of 30° to 60°. The angle formed between the upper surface and the inclined surface of the second mirror member 30b may be equal to or different from the angle formed between the lower surface and the inclined surface of the first mirror member 30a.

The second mirror member 30b has the second reflective surface 30bs. A portion of the second reflective surface 30bs is positioned above at least a portion of the first reflective surface 30as of each first mirror surface 30a. As illustrated in FIG. 1D, the second mirror member 30b, more specifically the second reflective surface 30bs thereof, reflects the laser beam L reflected by the first reflective surface 30as and transmitted through the cover 40A to further change the travel direction of the laser beam L to the +Z direction. The second mirror member 30b may be a single member unlike the plurality of first mirror members 30a. When the second mirror member 30b is a single member, the deviation of the optical axis due to misalignment of the member can be reduced.

With the positions of the plurality of first mirror members 30a in the Z direction being different from each other, the heights of the optical axes of the plurality of laser beams L reflected by the second reflective surface 30bs with respect to the mounting surface 10s as a height reference plane are different from each other. This is because the distance between a point where the optical axis of the laser beam L meets the first reflective surface 30as, and a point where the optical axis of the laser beam L meets the second reflective surface 30bs, depends on the position of the first reflective surface 30as in the Z direction.

In the example of FIG. 1D, the plurality of first mirror members 30a are arranged along the X direction to be gradually shifted in the −Z direction, and therefore, the heights of the optical axes of the plurality of laser beams L reflected by the second reflective surface 30bs decrease gradually along the +X direction. The absolute value of the difference in height between two adjacent ones of the plurality of laser beams L is, for example, 0.3 mm to 0.5 mm.

As illustrated in FIG. 1D, there is a resin layer 32 between the lower surface of the second mirror member 30b and the upper surface 42 of the cover 40A. The resin layer 32 is formed by bringing the lower surface of the second mirror member 30b into contact with the upper surface 42 of the cover 40A with an uncured resin located therebetween and then curing the resin. The resin may, for example, be a thermosetting resin, which is adapted to be cured by heating, or a photocurable resin, which is adapted to be cured by irradiation with ultraviolet or visible light. Active alignment may be performed before curing of the resin as follows. Specifically, while each laser light source 20 is emitting a laser beam L, the position and orientation of the second mirror member 30b are appropriately adjusted such that the second reflective surface 30bs changes the travel directions of the plurality of laser beams L into the +Z direction.

By rotating the second mirror member 30b around the X axis or Y axis as the axis of rotation to change the orientation of the second mirror member 30b, the travel directions of the laser beams L can be adjusted. By rotating the second mirror member 30b around the X axis as the axis of rotation, the travel directions of the laser beams L can be changed vertically. By rotating the second mirror member 30b around the Y axis as the axis of rotation, the travel directions of the laser beams L can be changed laterally with respect to the front direction.

Furthermore, by adjusting the position of the second mirror member 30b in the Z direction, the heights of the optical axes of the laser beams L can be adjusted. By shifting the second mirror member 30b in the +Z direction, the heights of the optical axes of the laser beams L can be decreased. By shifting the second mirror member 30b in the −Z direction, the heights of the optical axes of the laser beams L can be increased.

The first mirror members 30a and the second mirror member 30b, which are, for example, a support having an inclined surface, have a reflective surface. The support may, for example, be formed of at least one selected from the group consisting of glass, quartz, synthetic quartz, sapphire, ceramics, silicon, metals and dielectric materials. The reflective surface may, for example, be formed of a reflective material such as a dielectric multilayer film or a metal material. The reflective surface corresponds to the first reflective surface 30as and the second reflective surface 30bs.

Alternatively, first mirror member 30a and the second mirror member 30b may, for example, include a support having an inclined surface. The support may be formed of the above reflective material. In that case, the inclined surface of the support corresponds to the first reflective surface 30as and the second reflective surface 30bs.

### Cover 40A

As illustrated in FIG. 1B, the cover 40A has the upper surface 42 and the lower surface 44. The lower surface 44 of the cover 40A faces the mounting surface 10s of the base 10A, and the upper surface 42 of the cover 40A is positioned at a side opposite to the lower surface 44 of the cover 40A. In the present specification, the lower surface 44 of the cover 40A is also referred to as a “counter surface.” The cover 40A is positioned above the plurality of semiconductor laser elements 22 and the plurality of first mirror members 30a. The cover 40A transmits the laser beam L reflected by the first reflective surface 30as of each first mirror member 30a. More specifically, the cover 40A has a plurality of light transmission portions 46. Each light transmission portion 46 transmits the laser beam L reflected by the first reflective surface 30as of a corresponding first mirror member 30a.

The cover 40A may have a light-blocking film 48 in an area of the lower surface 44 at least around the lower surface of each of the plurality of light transmission portions 46. the lower surface of the light transmission portion 46 has a rectangular shape in the example of FIG. 1B, but is not limited thereto. The shape of the lower surface of the light transmission portion 46 may, for example, be circular or elliptical.

The light-blocking film 48 allows for reducing the possibility that stray light generated in the light-emitting device 100A, which is not the laser beam L, leaks out of the light-emitting device 100A. This effect reduces the possibility that stray light generated in the light-emitting device 100A, which is not the laser beam L, reaches the resin layer 32 of FIG. 1D, and therefore, the degradation of the resin layer 32 can be effectively reduced. Furthermore, with the light-blocking film 48, when the resin layer 32 is formed by irradiation with ultraviolet or visible light, the ultraviolet or visible light is less likely to reach the laser light source 20. The light-blocking film 48 also reduces the possibility that the laser beam L emitted out of the light-emitting device 100A returns and reaches the laser light source 20. If the irradiation with the ultraviolet or visible light or the returning light can be reduced, the laser light source 20 is less likely to be damaged.

In the example of FIG. 1B, the light-blocking film 48 is provided on the entire lower surface 44 excluding the lower surfaces of the plurality of light transmission portions 46. The light-blocking film 48 thus provided further reduces the possibility that the stray light leaks out of the light-emitting device 100A, and the possibility that the ultraviolet or visible light or the returning light reaches the laser light source 20. The light-blocking film 48 is not necessarily provided on the lower surface 44 of the cover 40A.

The light transmission portions 46 of the cover 40A, which transmit the laser beams L, may, for example, have a transmittance of 60% or more, preferably 80% or more, with respect to the laser beams L. The other portion of the cover 40A may or may not have such a transmittance.

The cover 40A may, for example, be formed of at least one light transmissive material selected from the group consisting of glass, silicon, quartz, synthetic quartz, sapphire and transparent ceramics. A size in the X direction of the cover 40A may, for example, be in a range of 6 mm to 44 mm; in the Y direction, in a range of 0.1 mm to 1.5 mm; in the Z direction, in a range of 10 mm to 20 mm.

The light-blocking film 48 may be formed of a metal material such as Ag, Cu, W, Au, Ni, Pt, Sn, Ti and Pd. The light-blocking film 48 may, for example, be formed by photolithography. Alternatively, the light-blocking film 48 may, for example, be formed by disposing a metal film on the entire lower surface 44 of the cover 40A and then patterning the metal film by etching.

A peripheral region of the light-blocking film 48 is bonded to the metal film 16, which is disposed on the first upper surface 12a of the base 10A, by an inorganic bonding member such as a solder material. In the case in which the light-blocking film 48 is formed of a metal material similar to that for the metal film 16, the base 10A and the cover 40A may, for example, be bonded together by an inorganic bonding member disposed on the light-blocking film 48. It should be noted that the metal film 16 may be disposed on the lower surface 44 of the cover 40A separately from the light-blocking film 48.

In addition, the cover 40A has a flat plate shape in the example of FIGS. 1A to 1C, but is not limited thereto. The base 10A may have a flat plate shape, and the cover 40A may have a box shape that is open on the bottom side. In the case of such a shape, the base 10A and the cover 40A are bonded together such that the lower surface of the cover 40A is supported by a peripheral region of the mounting surface 10s of the base 10A. Alternatively, the base 10A may have a box shape that is open on the top side, and the cover 40A may have a box shape that is open on the bottom side. In the case of such a shape, the base 10A and the cover 40A are bonded together such that the lower surface of the cover 40A is supported by an upper surface of the base 10A.

### Slow-Axis Collimating Lens Array 50

As illustrated in FIG. 1A, the slow-axis collimating lens array 50 is arranged on the upper surface 42 of the cover 40A, and includes a plurality of slow-axis collimating lenses 50s. In the example of FIGS. 1A and 1B, the slow-axis collimating lens array 50 is formed in a monolithic body. When an element is formed as a single monolithic body, the influence of misalignment that occurs when the element is arranged can be reduced. The plurality of slow-axis collimating lenses 50s may be separate pieces.

As illustrated in FIG. 1D, each of the plurality of slow-axis collimating lenses 50s collimates the laser beam L that has been emitted from a corresponding one of the plurality of laser light sources 20 and reflected by the first reflective surface 30as and the second reflective surface 30bs sequentially in this order, in the XZ plane, more specifically in the slow-axis direction in the XZ plane. As the slow-axis collimating lens array 50 is arranged on the upper surface 42 of the cover 40A, the laser beam L can be collimated before greatly diverging in the XZ plane. Therefore, the slow-axis collimating lens array 50 can be reduced in size. Each slow-axis collimating lens 50s may, for example, be formed of a light transmissive material similar to that of the cover 40.

A wedge prism may be provided between the second mirror member 30b and the slow-axis collimating lens array 50 so that the laser beams L are reflected by the second reflective surface 30bs to travel toward the slow-axis collimating lens array 50 and then pass through the wedge prism. Such a configuration can correct the optical path of the laser beam L entering each slow-axis collimating lens 50s.

Thus, in the light-emitting device 100A according to the first embodiment, although the mounting surface 10s, on which the plurality of laser light sources 20 are mounted, extends in a single plane, the heights of the optical axes of the plurality of laser beams L can be caused to be different from each other with respect to the mounting surface 10s as a height reference plane. Furthermore, in the case in which the mounting surface 10s extends in a single plane, variations in the amount of heat generated by the plurality of laser light sources 20 during driving and transmitted to the mounting surface of the support base body can be reduced. As a result, heat generated by the plurality of laser light sources 20 during driving can be effectively transmitted to the outside of the light-emitting device 100A.

The light-emitting device 100A may, for example, be fabricated as follows. In the first step, the base 10A, the plurality of laser light sources 20, the plurality of first mirror members 30a, the second mirror member 30b, the cover 40A and the slow-axis collimating lens array 50 are provided. In the next step, the plurality of laser light sources 20 and the plurality of first mirror members 30a are disposed on the mounting surface 10s of the base 10A. In the next step, the cover 40A is bonded to the base 10A. In the next step, active alignment is performed in a state in which the lower surface of the second mirror member 30b is in contact with the upper surface 42 of the cover 40A with an uncured resin disposed therebetween. In the next step, the resin is cured, so that the resin layer 32 is formed between the second mirror member 30b and the cover 40A. In the next step, the slow-axis collimating lens array 50 is disposed on the upper surface 42 of the cover 40A.

### Variations of Light-Emitting Device 100A

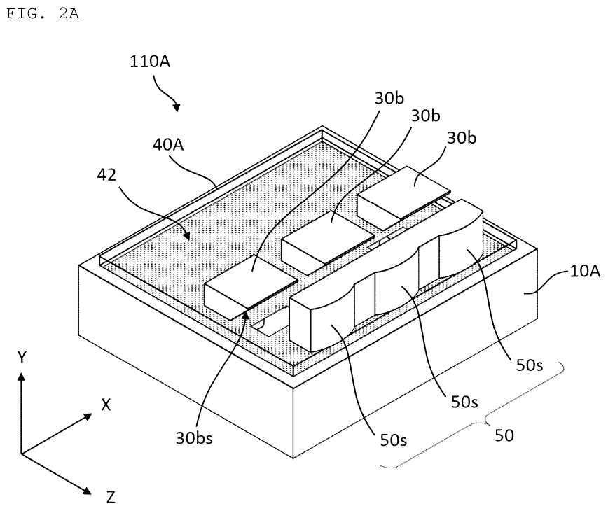

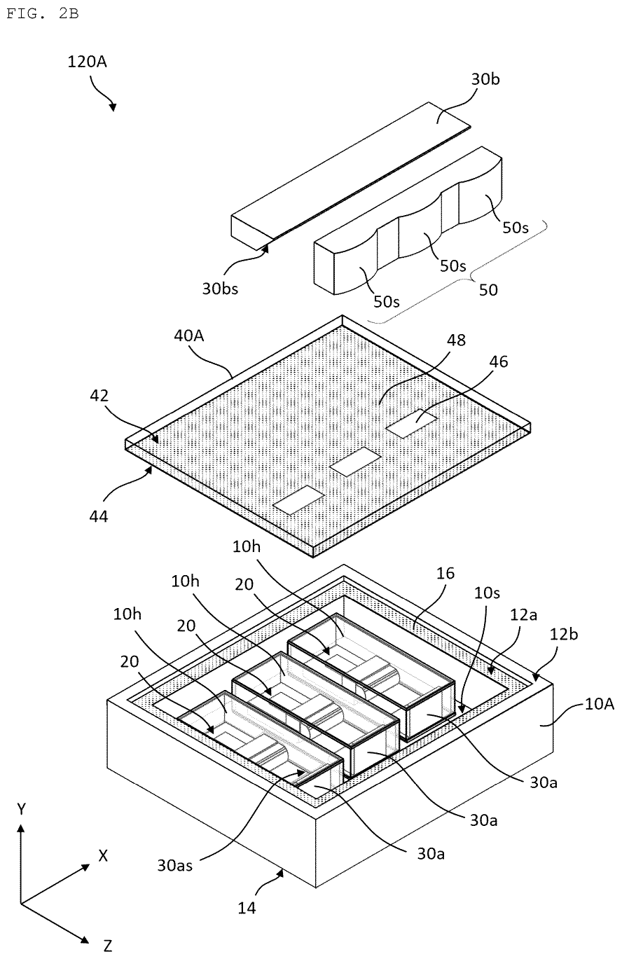

Next, Variations 1 and 2 of the light-emitting device 100A according to the first embodiment will be described with reference to FIGS. 2A and 2B, respectively.

FIG. 2A is a perspective view schematically illustrating Variation 1 of the light-emitting device according to the first embodiment of the present disclosure. The light-emitting device 110A of FIG. 2A is different from the light-emitting device 100A of FIG. 1A in that the light-emitting device 110A includes a plurality of second mirror members 30b instead of the single second mirror member 30b. The number of second mirror members 30b is the same as the number of laser light sources 20. The inside of the light-emitting device 110A is the same as that of the light-emitting device 100A of FIG. 1B. At least a portion of the second reflective surface 30bs of each second mirror member 30b is positioned above at least a portion of the first reflective surface 30as of a corresponding first mirror member 30a. The laser beam L emitted from each laser light source 20 is reflected by the first reflective surface 30as of a corresponding first mirror member 30a and the second reflective surface 30bs of a corresponding second mirror member 30b sequentially in the stated order. The positions and orientations of the plurality of second mirror members 30b can be adjusted separately, and therefore, a deviation of the travel direction of each of the plurality of laser beams L from the +Z direction can be effectively reduced.

FIG. 2B is an exploded perspective view schematically illustrating a configuration of Variation 2 of the light-emitting device according to the first embodiment of the present disclosure. The light-emitting device 120A of FIG. 2B is different from the light-emitting device 100A of FIG. 1A in that the light-emitting device 120A includes a plurality of housings 10h arranged on the mounting surface 10s. Each of the plurality of housings 10h houses a respective one of the plurality of laser light sources 20, and one of the plurality of first mirror members 30a that corresponds to the respective one of the plurality of laser light sources 20. In this case, the laser light source 20 and the first mirror member 30a are arranged on the mounting surface 10s via the housing 10h.

The housing 10h that houses the laser light source 20 and the first mirror member 30a can be handled as a single unit. Therefore, by arranging the plurality of units on the mounting surface 10s, the plurality of laser light sources 20 and the plurality of first mirror members 30a can be easily placed in the base 10A. Furthermore, sealing, more preferably hermetically sealing, the laser light source 20 and the first mirror member 30a by the housing 10h allows for improving the durability of the laser light source 20 and the first mirror member 30a.

The housing 10h transmits the laser beam L that has been emitted from the laser light source 20 and reflected by the first reflective surface 30as of the first mirror member 30a. In FIG. 2B, for ease of description, the housing 10h is shown as transparent so that the inside thereof can be viewed. However, as long as a light transmission portion of the housing 10h that transmits the laser beam L is configured to transmit light, the other portion of the housing 10h may or may not be configured to transmit light.

### Light-Emitting Module

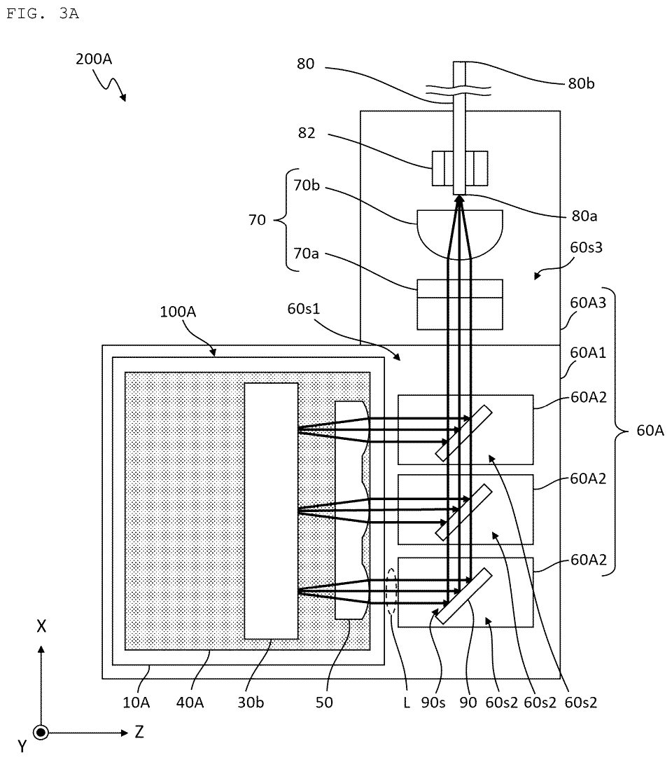

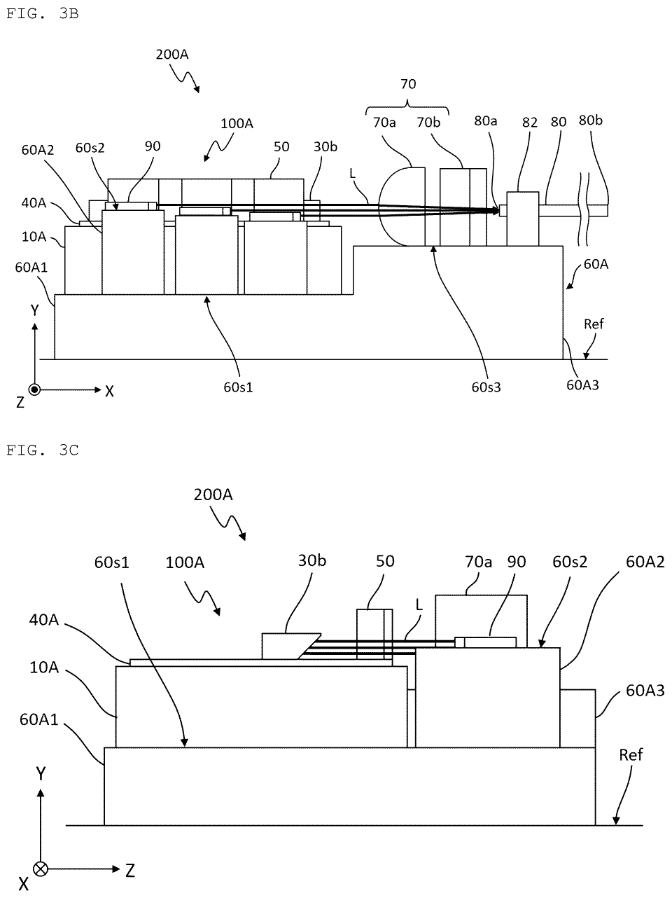

Next, an example configuration of a light-emitting module according to the first embodiment of the present disclosure will be described with reference to FIGS. 3A to 3C. While the light-emitting module herein includes the light-emitting device 100A of FIG. 1, the light-emitting device 100A may be used in other applications instead of being employed in the light-emitting module.

FIG. 3A is a top view schematically illustrating an example configuration of the light-emitting module according to the first embodiment of the present disclosure. FIG. 3B is a side view schematically illustrating an example configuration of the light-emitting module according to the first embodiment of the present disclosure. FIG. 3C is another side view schematically illustrating an example configuration of the light-emitting module according to the first embodiment of the present disclosure.

The light-emitting module 200A of FIGS. 3A to 3C includes a support base body 60A, a condensing lens 70, an optical fiber 80, a support member 82 that supports the optical fiber 80, a plurality of mirror members 90 and the light-emitting device 100A. Each mirror member 90 has a reflective surface 90s.

As illustrated in FIG. 3B, the support base body 60A is arranged on a reference plane Ref that is parallel to the XZ plane. The reference plane Ref is a height reference plane in the light-emitting module 200A. As illustrated in FIG. 3A, the support base body 60A includes a first portion 60A1 that supports the light-emitting device 100A. The support base body 60A further includes a plurality of second portions 60A2 that are supported by the first portion 60A1. Each second portion 60A2 supports a corresponding mirror member 90. The support base body 60A further includes a third portion 60A3 that is connected to the first portion 60A1. The third portion 60A3 supports the condensing lens 70 and the optical fiber 80.

The first portion 60A1 has a first placement surface 60s1. In the first placement surface 60s1, the plurality of second portions 60A2 are arranged. Each second portion 60A2 has a second placement surface 60s2. The third portion 60A3 has a third placement surface 60s3.

The first placement surface 60s1 is a surface parallel to the XZ plane. As illustrated in FIG. 3B, the heights of the plurality of second placement surfaces 60s2 decrease gradually along the +X direction. As illustrated in FIG. 3A, in addition to the plurality of second portions 60A2, the light-emitting device 100A is arranged on the first placement surface 60s1. The lower surface 14 of the base 10A illustrated in FIG. 1B included in the light-emitting device 100A is bonded to the first placement surface 60s1 of the support base body 60A by an inorganic bonding member such as a solder material. A metal film may be provided on the lower surface 14 of the base 10A. On each second placement surface 60s2, a corresponding mirror member 90 is provided. In the case in which the mirror member 90 has a sufficiently great size in the Y direction, the mirror member 90 may be arranged on the first placement surface 60s1 without providing the second portion 60A2 therebetween. On the third placement surface 60s3, the condensing lens 70 is arranged, and the optical fiber 80 is arranged with the support member 82 located therebetween.

In the example of FIG. 3B, the height of the third placement surface 60s3 from the reference plane Ref is greater than the height of the first placement surface 60s1 from the reference plane Ref, and is smaller than the smallest of the heights of the plurality of second placement surfaces 60s2 from the reference plane Ref. The height of the third placement surface 60s3 may be equal to or smaller than the height of the first placement surface 60s1, depending on a size in the Y direction of the condensing lens 70. Alternatively, the height of the third placement surface 60s3 may be equal to or greater than the greatest of the heights of the plurality of second placement surfaces 60s2.

The support base body 60A may, for example, be formed of a ceramic selected from the group consisting of AN, SiN, SiC and alumina. Alternatively, the support base body 60A may, for example, be formed of at least one metal material selected from the group consisting of Cu, Al and W. The support base body 60A may, for example, be formed of a metal matrix composite material in which diamond particles are dispersed in at least one metal material selected from the group consisting of Cu, Al and W. The support base body 60A may be monolithically formed or may be an assembly of a plurality of parts. The plurality of parts may be formed of the same material or different materials. For example, the first portion 60A1, the plurality of second portions 60A2 and the third portion 60A3 may be monolithically formed with each other or may be formed separately from each other. Alternatively, the first portion 60A1 and the third portion 60A3 may be monolithically formed with each other, and the plurality of second portions 60A2 may be formed separately from the first portion 60A1 and the third portion 60A3.

The support base body 60A may be formed of a metal material selected from the group consisting of Cu, Al and W, and may preferably be a single member. The metal material has a heat dissipation performance higher than ceramics, and is soft and therefore easy to process.

The support base body 60A serves as a support base on which the light-emitting device 100A is arranged. The support base body 60A may also serve as a heat sink that transmits heat generated by the light-emitting device 100A to the outside to reduce an excessive increase in the temperature of the light-emitting device 100A. In that case, one or more flow paths for liquid cooling may be provided in the support base body 60A. Water may, for example, be used for the liquid cooling. A fin structure for air cooling may be provided on a surface of the support base body 60A. Alternatively, in the case in which the support base body 60A is arranged in a heat sink provided separately, the support base body 60A may serve as a heat spreader that transmits heat generated by the light-emitting device 100A to the heat sink.

As illustrated in FIGS. 3A and 3C, the light-emitting device 100A emits a plurality of laser beams L in the +Z direction. In the light-emitting device 100A of FIG. 1B, each laser beam L is emitted from the corresponding laser light source 20, and is reflected by the first reflective surface 30as and the second reflective surface 30bs sequentially in this order. Each laser beam L is collimated in the XZ plane and the YZ plane. As illustrated in FIGS. 3A and 3B, the reflective surface 90s of each mirror member 90 reflects the corresponding laser beam L to change the travel direction of the laser beam L into the +X direction toward the condensing lens 70.

Each laser beam L is represented by three thick lines with an arrow in the example of FIG. 3A, and is represented by a single thick line with an arrow in the examples of FIGS. 3B and 3C. In the example of FIG. 3A, the laser beam L is represented by the three thick lines with an arrow in order to emphasize the divergence of the laser beam L.

The travel directions of all or some of the plurality of laser beams L emitted from the light-emitting device 100A may actually deviate from the +Z direction. Even in such a case, the deviation of the travel direction of the laser beam L reflected by the reflective surface 90s from the +X direction can be reduced by appropriately adjusting the position and orientation of the mirror member 90 of FIG. 3A. An angle formed between the travel direction of the laser beam L reflected by the reflective surface 90s and the +X direction is preferably 1° or less, more preferably 0.1° or less, for example.

The condensing lens 70 has a fast-axis condensing lens 70a and a slow-axis condensing lens 70b. The fast-axis condensing lens 70a may, for example, be a cylindrical lens having a uniform cross-sectional shape in the Z direction, and the slow-axis condensing lens 70b may, for example, be a cylindrical lens having a uniform cross-sectional shape in the Y direction. The optical axis of each of the fast-axis condensing lens 70a and the slow-axis condensing lens 70b is parallel to the X direction. The condensing lens 70 may be formed of the above light transmissive material as with the cover 40A of FIGS. 1A and 1B.

The fast-axis condensing lens 70a is arranged such that the focal point thereof substantially coincides with a light incident end 80a of the optical fiber 80. Similarly, the slow-axis condensing lens 70b is arranged such that the focal point thereof substantially coincides with the light incident end 80a of the optical fiber 80. The focal length of the fast-axis condensing lens 70a is longer than that of the slow-axis condensing lens 70b. As illustrated in FIG. 3B, the fast-axis condensing lens 70a converges the plurality of laser beams L to the light incident end 80a of the optical fiber 80 in the XY plane. As illustrated in FIG. 3A, the slow-axis condensing lens 70b converges each laser beam L to the light incident end 80a in the XZ plane.

Thus, each of the plurality of laser beams L emitted in the +Z direction from the light-emitting device 100A is reflected by the corresponding reflective surface 90s to travel in the +X direction. More specifically, the laser beam L emitted from each of the plurality of laser light sources 20 included in the light-emitting device 100A is reflected by the first reflective surface 30as, the second reflective surface 30bs and the reflective surface 90s sequentially in this order to travel in the +X direction. The plurality of laser beams L thus obtained can be combined by the condensing lens 70, and then can enter the optical fiber 80.

As a result, the light-emitting module 200A emits a combined beam, in which the plurality of laser beams L are combined, from a light emission end 80b of the optical fiber 80. The power of the combined beam is substantially equal to the power of each laser beam L multiplied by the number of the laser beams L. Therefore, the power of the combined beam can be increased by increasing the number of laser beams L.

In the present description, the following specific directions in the first embodiment may be designated with numbers. In the light-emitting device 100A, the direction in which the laser beam L is emitted from the laser light source 20 is also referred to as a “first direction,” and the direction in which the plurality of laser light sources 20 are arranged is also referred to as a “second direction.”
In the light-emitting module 200A, the direction in which the laser beam L is reflected by the reflective surface 90s of each mirror member 90 is also referred to as a “third direction.”
In the above example, the first direction is the +Z direction, the second direction is the +X direction, and the third direction is the +X direction, but is not limited thereto. The second direction but does not need to be orthogonal to the first direction as long as it intersects the first direction. The third direction may or may not be parallel to the second direction.

### Second Embodiment

### Light-Emitting Device

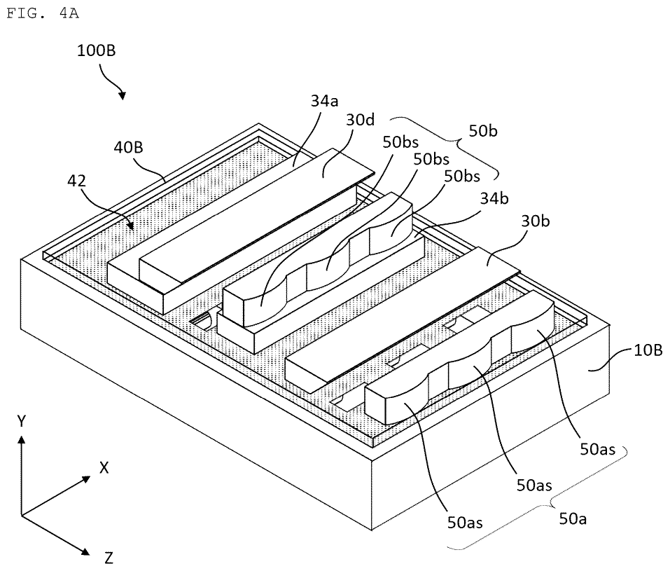

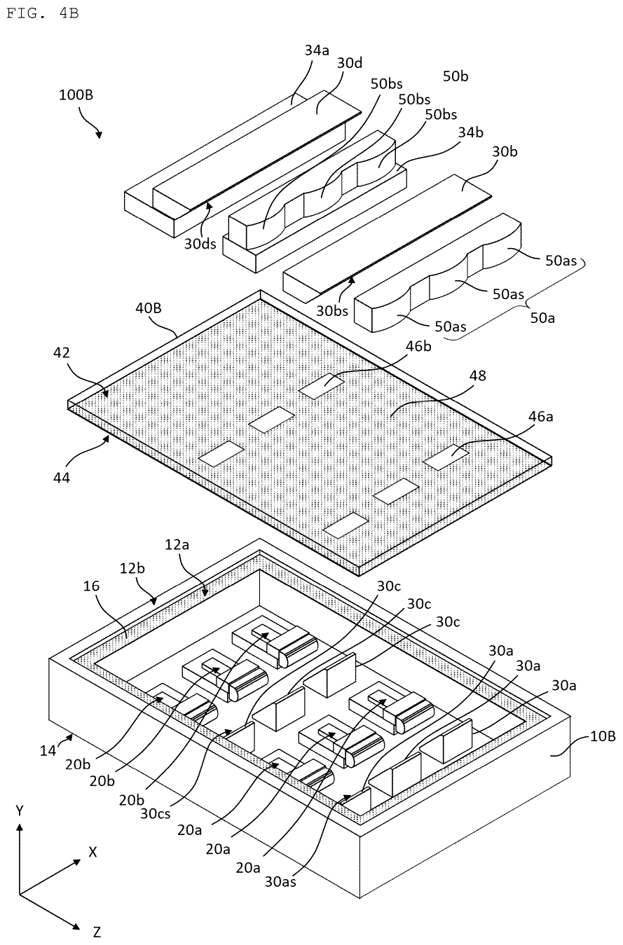

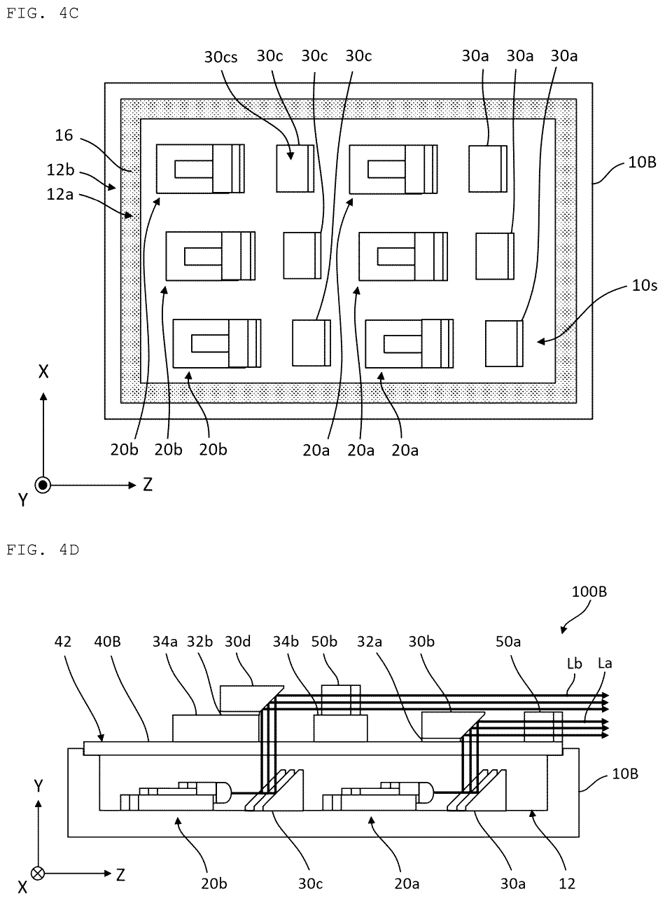

An example configuration of a light-emitting device according to a second embodiment of the present disclosure will be described with reference to FIGS. 4A to 4D. FIG. 4A is a perspective view schematically illustrating an example configuration of the light-emitting device according to the second embodiment of the present disclosure. The light-emitting device 100B of FIG. 4A may, for example, be arranged on a placement surface of a support base body. Details of the support base body will be described below in the description of the light-emitting module according to the second embodiment. FIG. 4B is an exploded perspective view of the light-emitting device of FIG. 4A. The light-emitting device 100B of FIG. 1B includes a base 10B, a plurality of first laser light sources 20a, a plurality of second laser light sources 20b, a plurality of first mirror members 30a, a second mirror member 30b, a plurality of third mirror members 30c, a fourth mirror member 30d, a cover 40B, a first slow-axis collimating lens array 50a, a second slow-axis collimating lens array 50b, a first support member 34a and a second support member 34b. The first slow-axis collimating lens array 50a is formed in a monolithic body, including a plurality of first slow-axis collimating lenses 50as. Similarly, the second slow-axis collimating lens array 50b is formed in a monolithic body, including a plurality of second slow-axis collimating lenses 50bs. In the example of FIG. 4B, the number of first laser light sources 20a is three, but is not limited thereto. The number of first laser light sources 20a may be two, or four or more. The number of first mirror members 30a and the number of first slow-axis collimating lenses 50as are preferably the same as the number of first laser light sources 20a. In addition, the number of second laser light sources 20b is three, but is not limited thereto. The number of second laser light sources 20b may be two, or four or more. The number of second mirror members 30b and the number of second slow-axis collimating lenses 50bs are preferably the same as the number of second laser light sources 20b.

The first laser light source 20a corresponds to the laser light source 20 of FIG. 1B. The first mirror member 30a corresponds to the first mirror member 30a of FIG. 1B. The second mirror member 30b corresponds to the second mirror member 30b of FIG. 1B. The first slow-axis collimating lens array 50a corresponds to the slow-axis collimating lens array 50 of FIG. 1B.

The light-emitting device 100B of FIG. 4B is different from the light-emitting device 100A of FIG. 1B in the following four points.

A first point is that the light-emitting device 100B includes the base 10B instead of the base 10A. A size of the base 10B in the Z direction is greater than that of the base 10A.

A second point is that the light-emitting device 100B includes the plurality of second laser light sources 20b and the plurality of third mirror members 30c in addition to the plurality of first laser light sources 20a and the plurality of first mirror members 30a. Each third mirror member 30c has a third reflective surface 30cs.

A third point is that the light-emitting device 100B of FIG. 4B includes the fourth mirror members 30d and the second slow-axis collimating lens array 50b in addition to the second mirror member 30b and the first slow-axis collimating lens array 50a. The fourth mirror member 30d has a fourth reflective surface 30ds.

A fourth point is that the light-emitting device 100B of FIG. 4B includes the first support member 34a that supports the fourth mirror members 30d, and the second support member 34b that supports the second slow-axis collimating lens array 50b.

FIG. 4C is a top view of the light-emitting device 100B of FIG. 4B with the cover 40B and the components on the cover 40B removed. FIG. 4D is a cross-sectional view of the light-emitting device 100B of FIG. 4A taken parallel to the YZ plane.

As will be described in detail below, as illustrated in FIG. 4D, the light-emitting device 100B according to the second embodiment can emit not only a plurality of first laser beams La, but also a plurality of second laser beams Lb that travel above the plurality of first laser beams La. As a result, in a light-emitting module including the light-emitting device 100B, the number of laser beams to be combined can be increased, and therefore, the power of a combined beam can be increased.

Components of the light-emitting device 100B will be described below. The first laser light source 20a, the first mirror member 30a, the second mirror member 30b and the first slow-axis collimating lens array 50a are those as described in the first embodiment.

### Base 10B

The base 10B is different from the base 10A of FIG. 1B in a size in the Z direction. The base 10B houses the plurality of second laser light sources 20b and the plurality of third mirror members 30c in addition to the plurality of first laser light sources 20a and the plurality of first mirror members 30a. Therefore, a size of the base 10B in the Z direction is greater than that of the base 10A. As with the base 10A, the base 10B has mounting surface 10s, a first upper surface 12a, a second upper surface 12b and a lower surface 14.

The size of the base 10B in the X direction may, for example, 7 mm to 45 mm; in the Y direction, 2 mm to 3 mm; and in the Z direction, 25 to 35 mm.

### Second Laser Light Source 20b

The second laser light source 20b has the same structure as that of the first laser light source 20a. The second laser light source 20b is different from the first laser light source 20a in a position where the second laser light source 20b is arranged. As illustrated in FIG. 4B, the plurality of second laser light sources 20b are arranged further rearward than the plurality of first laser light sources 20a on the mounting surface 10s of the base 10B. Each first laser light source 20a emits the first laser beam La in the +Z direction, and each second laser light source 20b emits the second laser beam Lb in the +Z direction. The term “rearward” means a direction that is opposite to the direction in which the first laser beam La is emitted from each first laser light source 20a and to the direction in which the second laser beam Lb is emitted from each second laser light source 20b.

As illustrated in FIG. 4C, the plurality of second laser light sources 20b are arranged in the X direction such that the positions of the plurality of laser light sources 20b in the Z direction are different from each other. In the example of FIG. 4C, the plurality of second laser light sources 20b are arranged along the X direction so as to be gradually shifted in the −Z direction. The plurality of second laser light sources 20b may be shifted in the +Z direction, which is opposite to the −Z direction, instead of the −Z direction. Alternatively, the positions in the Z direction of the plurality of second laser light sources 20b, which are arranged in the X direction, may be irregular.

In the case in which the mounting surface 10s extends in a single plane, variations in the amount of heat generated by the plurality of first laser light sources 20a and the plurality of second laser light sources 20b during driving and transmitted to the placement surface of the support base body can be reduced. In other words, in the case in which the mounting surface 10s extends in a single plane, heat generated by the laser light sources 20 can be dissipated uniformly. As a result, heat generated by the plurality of first laser light sources 20a and the plurality of second laser light sources 20b during driving can be effectively transmitted to the outside of the light-emitting device 100B.

The second laser light source 20b has the same structure as that of the first laser light source 20a. In the present specification, the semiconductor laser element 22 included in each first laser light source 20a is referred to as a “first semiconductor laser element,” and the semiconductor laser element 22 included in each second laser light source 20b is referred to as a “second semiconductor laser element.” The first semiconductor laser element has a first light emission surface, and the first laser beam La is emitted in the +Z direction from the first light emission surface. The second semiconductor laser element has a second light emission surface, and the second laser beam Lb is emitted in the +Z direction from the second light emission surface.

### Third Mirror Member 30c and Fourth Mirror Member 30d

The third mirror member 30c has the same structure as that of the first mirror member 30a. The third mirror member 30c is different from the first mirror member 30a in a position where the third mirror member 30c is arranged. As illustrated in FIG. 4B, the plurality of third mirror members 30c are arranged further rearward than the plurality of first mirror members 30a on the mounting surface 10s of the base 10B. As illustrated in FIG. 4C, the plurality of third mirror members 30c are arranged in the X direction such that the positions in the Z direction of the third reflective surface 30cs are different from each other. In the example of FIG. 4C, as with the plurality of second laser light sources 20b, the plurality of third mirror members 30c are arranged along the X direction so as to be gradually shifted in the −Z direction. The plurality of third mirror members 30c may be shifted in the +Z direction, which is opposite to the −Z direction, rather than the −Z direction. Alternatively, the positions in the Z direction of the plurality of third mirror members 30c, which are arranged in the X direction, may be irregular.

In the example of FIG. 4C, a plurality of distances that are each defined as a distance between a respective one of the plurality of third mirror members 30c and a corresponding one of the plurality of second laser light sources 20b are substantially the same.
The distance is between a point where the optical axis of the second laser beam Lb meets the third reflective surface 30cs of each third mirror member 30c, and the center of the light emission surface of the corresponding second laser light source 20b.

As illustrated in FIG. 4D, each third mirror member 30c, more specifically the third reflective surface 30cs thereof, reflects the second laser beam Lb emitted from the second laser light source 20b to change the travel direction of the second laser beam Lb into a direction that is away from the mounting surface 10s of the base 10B. An angle formed between the travel direction of the second laser beam Lb that is away from the mounting surface 10s of the base 10B, and the normal direction of the mounting surface 10s, may, for example, be 0°to 5°.

The fourth mirror member 30d has the same structure as that of the second mirror member 30b. The fourth mirror member 30d is different from the second mirror member 30b in a position where the fourth mirror member 30d is arranged. As illustrated in FIG. 4A, the fourth mirror member 30d is arranged on the upper surface 42 of the cover 40B further rearward than and above the second mirror member 30b with the first support member 34a located therebetween. In the case in which the fourth mirror member 30d has a sufficiently great size in the Y direction, it is not necessary to provide the first support member 34a.

As with the second mirror member 30b, the fourth mirror member 30d has the fourth reflective surface 30ds. A portion of the fourth reflective surface 30ds is positioned above at least a portion of the third reflective surface 30cs of each third mirror member 30c. As illustrated in FIG. 4D, the fourth mirror member 30d, more specifically the fourth reflective surface 30ds thereof, reflects the second laser beam Lb reflected by the third reflective surface 30cs to further change the travel direction of the second laser beam Lb into the +Z direction.

The fourth mirror member 30d is positioned above the second mirror member 30b, and therefore, the plurality of second laser beams Lb reflected by the fourth reflective surface 30ds travel in the +Z direction without impinging on the second mirror member 30b. As a result, the light-emitting device 100B can emit the plurality of first laser beams La, and the plurality of second laser beams Lb that travel above the plurality of first laser beams La.

The fourth mirror member 30d is a single member unlike the plurality of third mirror members 30c, and therefore, a deviation thereof from the optical axis due to misalignment of parts can be reduced. Instead of the fourth mirror member 30d, a plurality of separate fourth mirror members 30d may be used. The positions and orientations of the plurality of fourth mirror members 30d can be adjusted separately, and therefore, a deviation of the travel direction of each of the plurality of second laser beams Lb from the +Z direction can be effectively reduced.

As the positions in the Z direction of the plurality of third mirror members 30c are different from each other, the heights of the optical axes of the plurality of laser beams L reflected by the fourth reflective surface 30ds with respect to the mounting surface 10s as a height reference plane are different from each other. In the example of FIG. 4D, the plurality of third mirror members 30c are arranged along the X direction so as to be gradually shifted in the −Z direction, and therefore, the heights of the optical axes of the plurality of laser beams L reflected by the fourth reflective surface 30ds decrease gradually along the +X direction. The absolute value of the difference in height between the optical axes of two adjacent ones of the plurality of second laser beams Lb is, for example, 0.3 mm to 0.5 mm.

As illustrated in FIG. 4D, there is a first resin layer 32a between the lower surface of the second mirror member 30b and the upper surface 42 of the cover 40B. The first resin layer 32a corresponds to the resin layer 32 of FIG. 1D. Similarly, as illustrated in FIG. 4D, there is a second resin layer 32b between the lower surface of the fourth mirror member 30d and the upper surface of the first support member 34a. Therefore, as with the second mirror member 30b, the position and orientation of the fourth mirror member 30d can be appropriately adjusted.

### Cover 40B

As with the cover 40A of FIG. 1B, the cover 40B has an upper surface 42 and a lower surface 44. The cover 40B is different from the cover 40A of FIG. 1B in a size in the Z direction and a shape of the light-blocking film 48. A size in the Z direction of the cover 40B is greater than that of the cover 40A. The cover 40B is positioned above the plurality of first laser light sources 20a, the plurality of second laser light sources 20b, the plurality of first mirror members 30a, and the plurality of third mirror members 30c.

The cover 40B transmits the first laser beams La reflected by the first reflective surfaces 30as and the second laser beams Lb reflected by the third reflective surfaces 30cs. More specifically, the cover 40B includes a plurality of first light transmission portions 46a and a plurality of second light transmission portions 46b. Each first light transmission portion 46a transmits the first laser beam La reflected by the first reflective surface 30as of the corresponding first mirror member 30a, and each second light transmission portion 46b transmits the second laser beam Lb reflected by the third reflective surface 30cs of the corresponding third mirror member 30c.

The cover 40B has a light-blocking film 48 on the lower surface 44 at least around the lower surface of each of the plurality of first light transmission portions 46a and the lower surface of each of the second light transmission portions 46b. In the example of FIG. 4B, the light-blocking film 48 is provided in the entire region of the lower surface 44 except for the lower surface of each of the plurality of first light transmission portions 46a and the lower surface of each of the plurality of second light transmission portions 46b.

A size of the cover 40B in the X direction may, for example, be in a range of 6 mm to 44 mm; in the Y direction, in a range of 0.1 mm to 1.5 mm; and in the Z direction, in a range of 20 mm to 30 mm.

### Second Slow-Axis Collimating Lens Array 50b

The second slow-axis collimating lens array 50b has the Same structure as that of the first slow-axis collimating lens array 50a. The second slow-axis collimating lens array 50b is different from the first slow-axis collimating lens array 50a in a position where the second slow-axis collimating lens array 50b is arranged. As illustrated in FIG. 4A, the second slow-axis collimating lens array 50b is arranged on the upper surface 42 of the cover 40B further rearward than and above the first slow-axis collimating lens array 50a with the second support member 34b located therebetween. In the case in which the second slow-axis collimating lens array 50b has a sufficiently great size in the Y direction, it is not necessary to provide the second support member 34b.

As illustrated in FIG. 4D, each of the plurality of second slow-axis collimating lenses 50bs collimates, in the XZ plane, more specifically in the slow-axis direction in the XZ plane, the second laser beam Lb emitted by a corresponding one of the plurality of second laser light sources 20b and reflected by the third reflective surface 30cs and the fourth reflective surface 30ds sequentially in this order. With the second slow-axis collimating lens array 50b arranged on the upper surface 42 of the cover 40B via the second support member 34b, the second laser beam Lb can be collimated before greatly diverging in the XZ plane. Therefore, the second slow-axis collimating lens array 50b can be reduced in size. With the second slow-axis collimating lens array 50b positioned above the first slow-axis collimating lens array 50a, the second slow-axis collimating lens array 50b can receive the second laser beam Lb reflected by the fourth reflective surface 30ds. It should be noted that as the second slow-axis collimating lens array 50b is arranged above the first slow-axis collimating lens array 50a, the distance between the third reflective surface 30cs and the fourth reflective surface 30ds is longer than the distance between the first reflective surface 30as and the second reflective surface 30bs. Therefore, the second slow-axis collimating lens array 50b and the first slow-axis collimating lens array 50a may be arranged such that the distance between the fourth mirror member 30d and the second slow-axis collimating lens array 50b is shorter than the distance between the second mirror member 30b and the first slow-axis collimating lens array 50a. Such an arrangement allows the distance over which light beams emitted from the plurality of first laser light sources 20a travel before reaching the first slow-axis collimating lens array 50a to be the same as the distance over which light beams emitted from the plurality of second laser light sources 20b travel before reaching the second slow-axis collimating lens array 50b. In other words, a light beam emitted from the first slow-axis collimating lens array 50a and a light beam emitted from the second slow-axis collimating lens array 50b can be the same in shape. Instead of adjusting the distance, by providing the first slow-axis collimating lens array 50a and the second slow-axis collimating lens array 50b having different lens shapes, these slow-axis collimating lens arrays may be caused to emit light beams having the same shape. Also, these methods may be combined.

The light-emitting device 100B may be virtually divided into two structures by a plane parallel to the XY plane, and the resultant sub-structures may be sub-light-emitting devices. In other words, the light-emitting device 100B may include two sub-light-emitting devices. One of the sub-light-emitting devices includes the plurality of first laser light sources 20a, the plurality of first mirror members 30a, the second mirror member 30b, and the first slow-axis collimating lens array 50a. The other sub-light-emitting device includes the plurality of second laser light sources 20b, the plurality of third mirror members 30c, the fourth mirror member 30d, the second slow-axis collimating lens array 50b, the first support member 34a, and the second support member 34b. The two sub-light-emitting devices are arranged in the Z direction, and share the base 10B and the cover 40B. The number of sub-light-emitting devices is not limited to two and may be three or more.

Thus, in the light-emitting device 100B according to the second embodiment, even in the case in which the mounting surface 10s, on which the plurality of first laser light sources 20a and the plurality of second laser light sources 20b are mounted, extends in a single plane, the heights of the optical axes of the plurality of first laser beams La with respect to the mounting surface 10s as a height reference plane can be different from each other, and the heights of the optical axes of the plurality of second laser beams Lb with respect to the mounting surface 10s as a height reference surface can be different from each other. Furthermore, in the case in which the mounting surface 10s extends in a single plane, variations in heat generated by the plurality of first laser light sources 20a and the plurality of second laser light sources 20b during driving and transmitted to the mounting surface of the support base body can be reduced. As a result, heat generated by the plurality of first laser light sources 20a and the plurality of second laser light sources 20b during driving can be effectively transmitted to the outside of the light-emitting device 100B. Furthermore, the light-emitting device 100B can emit not only the plurality of first laser beams La, but also the plurality of second laser beams Lb that travel above the plurality of first laser beams La. As a result, in a light-emitting module including the light-emitting device 100B, the number of laser beams that can be combined can be increased, and therefore, the power of the combined beam can be further increased.

The light-emitting device 100B may, for example, be fabricated as follows. In a first step, the base 10B, the plurality of first laser light sources 20a, the plurality of second laser light sources 20b, the plurality of first mirror members 30a, the second mirror member 30b, the plurality of third mirror members 30c, the fourth mirror member 30d, the cover 40B, the first slow-axis collimating lens array 50a, the second slow-axis collimating lens array 50b, the first support member 34a, and the second support member 34b are provided. In the next step, the plurality of first laser light sources 20a, the plurality of second laser light sources 20b, the plurality of first mirror members 30a, and the plurality of third mirror members 30c are provided on the mounting surface 10s of the base 10B. In the next step, the cover 40B is bonded to the base 10B.

In the next step, active alignment is performed with the lower surface of the second mirror member 30b being in contact with the upper surface 42 of the cover 40B via an uncured resin. In the next step, the resin is cured, so that the first resin layer 32a is formed between the second mirror member 30b and the cover 40B. In the next step, the first slow-axis collimating lens array 50a is provided on the upper surface 42 of the cover 40B.

In the next step, the first support member 34a and the second support member 34b are disposed on the upper surface 42 of the cover 40B. In the next step, active alignment is performed with the lower surface of the fourth mirror member 30d being in contact with the upper surface of the first support member 34a via an uncured resin. In the next step, the resin is cured, so that the second resin layer 32b is formed between the fourth mirror member 30d and the upper surface of the first support member 34a. In the next step, the second slow-axis collimating lens array 50b is disposed on the upper surface of the second support member 34b.

### Light-Emitting Module

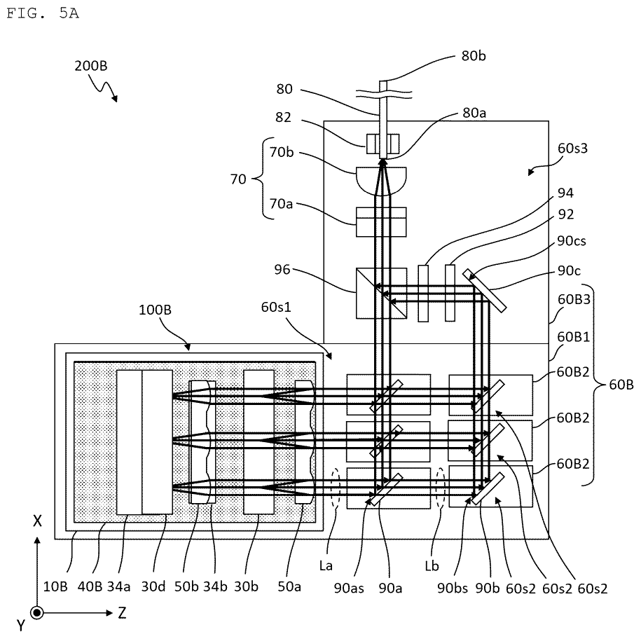

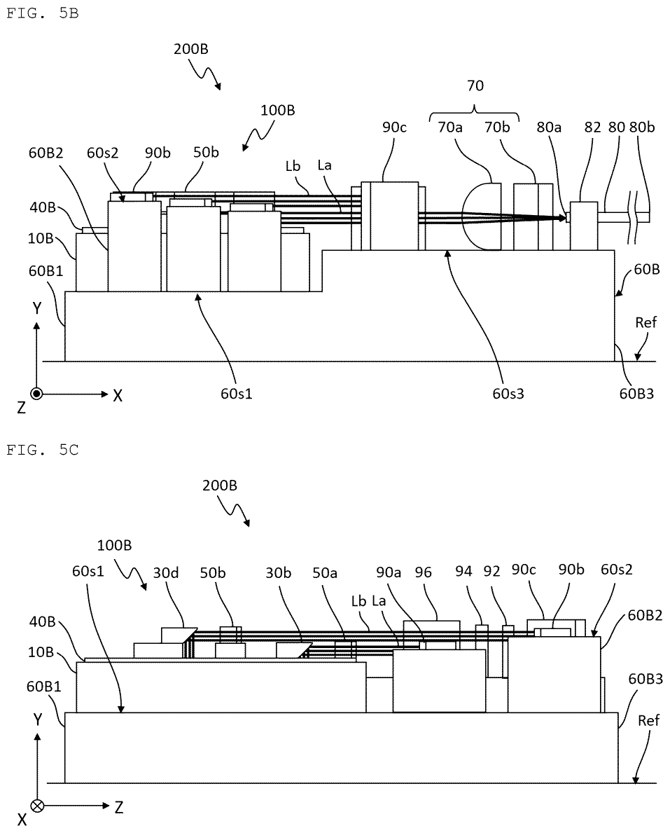

Next, an example configuration of a light-emitting module according to the second embodiment of the present disclosure will be described with reference to FIGS. 5A to 5C. While the light-emitting module herein includes the light-emitting device 100B of FIG. 4, the light-emitting device 100B may be used in other applications instead of being employed in the light-emitting module.

FIG. 5A is a top view schematically illustrating an example configuration of the light-emitting module according to the second embodiment of the present disclosure. FIG. 5B is a side view schematically illustrating an example configuration of the light-emitting module according to the second embodiment of the present disclosure. FIG. 5C is another side view schematically illustrating an example configuration of the light-emitting module according to the second embodiment of the present disclosure. The light-emitting module 200B of FIGS. 5A to 5C is different from the light-emitting module 200A of FIGS. 3A to 3C in the following three points.

A first point is that the light-emitting module 200B includes a support base body 60B instead of the support base body 60A. A shape of the support base body 60B is different from that of the support base body 60A. A second point is that the light-emitting module 200B includes the light-emitting device 100B, a plurality of mirror members 90a and a plurality of mirror members 90b instead of the light-emitting device 100A and the plurality of mirror members 90. Each mirror member 90a has a reflective surface 90as, and each mirror member 90b has a reflective surface 90bs. In the present specification, the mirror member 90a, and the mirror member 90 of FIG. 3A, are also referred to as a “fifth mirror member,” and the reflective surface 90as of the mirror member 90a and the reflective surface 90s of the mirror member 90 are also referred to as a “fifth reflective surface.” Similarly, the mirror member 90b is also referred to as a “sixth mirror member,” and the reflective surface 90bs thereof is also referred to as a “sixth reflective surface.” A third point is that the light-emitting module 200B further includes a mirror member 90c, a half-wave plate 92, an optical element 94 and a polarizing beam splitter 96. The mirror member 90c has a reflective surface 90cs.

The support base body 60B has a first portion 60B1 that supports the light-emitting device 100B. The support base body 60B further includes a plurality of second portions 60B2 that are supported by the first portion 60B1. The plurality of second portions 60B2 are arranged in two arrays. Each array is parallel to the X direction. Each second portion 60B2 included in the first array closer to the light-emitting device 100B supports a corresponding mirror member 90a. Each second portion 60B2 included in the second array further from the light-emitting device 100B supports a corresponding mirror member 90b. The support base body 60B further includes a third portion 60B3 that is connected to the first portion 60B1. The third portion 60B3 supports a condensing lens 70, an optical fiber 80, the mirror member 90c, the half-wave plate 92, the optical element 94, and the polarizing beam splitter 96.

The first portion 60B1 has a first placement surface 60s1 . The plurality of second portions 60B2 and the light-emitting device 100B are arranged on the first placement surface 60s1 . Each second portion 60B2 has a second placement surface 60s2 . The third portion 60B3 has a third placement surface 60s3.

The first placement surface 60s1 is a surface parallel to the XZ plane. As illustrated in FIG. 5B, the heights of the plurality of second placement surfaces 60s2 in each of the first and second arrays decrease gradually along the +X direction. On each second placement surface 60s2 in the first array, the corresponding mirror member 90a is arranged. On each second placement surface 60s2 in the second array, the corresponding mirror member 90b is arranged. In the case in which the mirror member 90a and the mirror member 90b have a sufficiently great size in the Y direction, the mirror member 90a and the mirror member 90b may be arranged on the first placement surface 60s1 without disposing the second portion 60B2 therebetween. The condensing lens 70, the mirror member 90c, the half-wave plate 92, the optical element 94, and the polarizing beam splitter 96 are arranged on the third placement surface 60s3, and the optical fiber 80 is arranged on the third placement surface 60s3 with the support member 82 located therebetween.

The light-emitting device 100B emits a plurality of first laser beams La and a plurality of second laser beams Lb in the +Z direction. In the light-emitting device 100B of FIG. 4B, each first laser beam La is emitted from a corresponding first laser light source 20a and reflected by the first reflective surface 30as and the second reflective surface 30bs sequentially in this order. In the light-emitting device 100B of FIG. 4B, each second laser beam Lb is emitted from a corresponding second laser light source 20b and reflected by the third reflective surface 30cs and the fourth reflective surface 30ds sequentially in this order. Each first laser beam La and each second laser beam Lb are collimated in the XZ plane and the YZ plane. As illustrated in FIG. 5C, the plurality of second laser beams Lb travel above the plurality of first laser beams La. The plurality of first laser beams La and the plurality of second laser beams Lb have the same polarization direction, which may, for example, be parallel to the X direction. The number of first laser beams La is three in the examples of FIGS. 5A and 5C, but is not limited thereto, and may be two, or four or more. This also holds true for the number of second laser beams Lb.

The reflective surface 90as of each mirror member 90a reflects a corresponding first laser beam La to change the travel direction of the first laser beam La into the +X direction. The reflective surface 90bs of each mirror member 90b reflects the corresponding second laser beam Lb to change the travel direction of the second laser beam Lb into the +X direction.

The reflective surface 90cs of the mirror member 90c reflects the second laser beam Lb traveling in the +X direction to change the travel direction of the second laser beam Lb into the −Z direction.

The half-wave plate 92 changes the polarization direction of the second laser beam Lb traveling in the −Z direction by 90°. The optical element 94 changes the heights of the optical axes of the plurality of second laser beams Lb such that the heights of the optical axes of the plurality of second laser beams Lb coincide with the heights of the optical axes of the plurality of first laser beams La. The optical element 94 may, for example, include at least one of a wedge, a prism and a set of two mirror members. The optical element 94 may be a light transmissive, flat plate-shaped wedge having a light incident surface and a light emission surface, which are parallel to each other. The wedge has a uniform cross-sectional shape in the X direction, and is arranged so as to be inclined from the +Y direction to the −Z direction. In the case in which the optical element 94 includes two mirror members, the reflective surface of one of the mirror members receives the second laser beam Lb traveling in the −Z direction to change the travel direction of the second laser beam Lb into the −Y direction. The reflective surface of the other mirror member receives the second laser beam Lb traveling in the −Y direction to change the travel direction of the second laser beam Lb into the −Z direction.

The polarizing beam splitter 96 transmits the plurality of first laser beams La that are traveling in the +X direction and whose polarization direction is the Z direction, and reflects the plurality of second laser beams Lb that are traveling in the −Z direction and whose polarization direction is the Y direction. Thus, the polarizing beam splitter 96 directs the plurality of second laser beams Lb that have passed through the half-wave plate 92 and the plurality of first laser beams La that have not passed through the half-wave plate 92, toward the condensing lens 70. Although in the example of FIG. 5A, the half-wave plate 92 is arranged on the optical paths of the plurality of second laser beams Lb, the half-wave plate 92 may be arranged on the optical paths of the plurality of first laser beams La. In that case, the polarizing beam splitter 96 directs the plurality of first laser beams La that have passed through the half-wave plate 92 and the plurality of second laser beams Lb that have not passed the half-wave plate 92, toward the condensing lens 70.

The plurality of first laser beams La and the plurality of second laser beams Lb that have passed through the polarizing beam splitter 96 are combined together by the condensing lens 70 to be converged at the light incident end 80a of the optical fiber 80.

Thus, each of the plurality of first laser beams La emitted in the +Z direction from the light-emitting device 100B is reflected in the +X direction by a corresponding reflective surface 90as, and each of the plurality of second laser beams Lb emitted in the +Z direction from the light-emitting device 100B is reflected in the +X direction by the corresponding reflective surface 90bs. More specifically, the first laser beam La emitted from each of the plurality of first laser light sources 20a included in the light-emitting device 100B is reflected by the first reflective surface 30as, the second reflective surface 30bs and the reflective surface 90as sequentially in this order. The second laser beam Lb emitted from each of the plurality of second laser light sources 20b included in the light-emitting device 100B is reflected by the third reflective surface 30cs, the fourth reflective surface 30ds and the reflective surface 90bs sequentially in this order. The plurality of first laser beams La and the plurality of second laser beams Lb thus obtained pass through the polarizing beam splitter 96 and enter the optical fiber 80, and then can be combined by the condensing lens 70.

As a result, the light-emitting module 200B emits, from the light emission end 80b of the optical fiber 80, a combined beam in which the plurality of first laser beams La and the plurality of second laser beams Lb are combined together. In the light-emitting module 200B of FIGS. 5A to 5C, the total number of the first laser beams La and the second laser beams Lb is two times as great as the number of the laser beams L in the light-emitting module 200A of FIGS. 3A to 3C. Therefore, the power of a combined beam can be increased.

In the present description, the following three specific directions in the second embodiment may be numbered. In the light-emitting device 100B, the direction in which the first laser beam La is emitted from the first laser light source 20a and the direction in which the second laser beam L a is emitted from the second laser light source 20b are also referred to as a “first direction.” The direction that intersects the first direction and in which the plurality of first laser light sources 20a and the plurality of second laser light sources 20b are arranged is also referred to as a “second direction.” In the light-emitting module 200B, the direction in which the second laser beam Lb is reflected by the reflective surface 90bs of each mirror member 90a and the direction in which the first laser beam La is reflected by the reflective surface 90as of each mirror member 90b are also referred to as a “third direction.”

In the above example, the first direction is the +Z direction, the second direction is the +X direction, and the third direction is the +X direction, but is not limited thereto. The second direction intersects the first direction, but does not need to be orthogonal to the first direction. The third direction may or may not be parallel to the second direction.

### Configuration of Laser Light Source 20

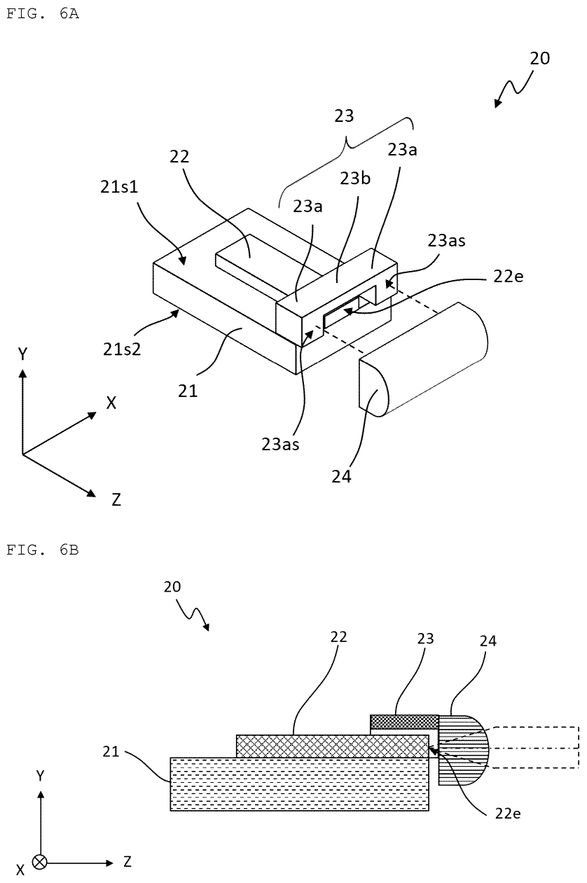

Next, an example configuration of the laser light source 20 of FIG. 1B will be described with reference to FIGS. 6A and 6B. FIG. 6A is an exploded perspective view of the laser light source 20. FIG. 6B is a cross-sectional view of the laser light source 20 taken parallel to the YZ plane. Each component of the laser light source 20 will be described below.

As illustrated in FIG. 6A, the submount 21 has an upper surface 21s1 and a lower surface 21s2 that are parallel to the XZ plane. A metal film is disposed on the upper surface 21s1. The semiconductor laser element 22 and the lens support member 23 are bonded to the submount 21 by, for example, an inorganic bonding member disposed on the metal film. The metal film provided on the upper surface 21s1 may be used to supply power to the semiconductor laser element 22. In addition, a metal film is provided at the lower surface 21s2. The base 10A and the laser light source 20 of FIG. 1B are bonded together by, for example, an inorganic bonding member disposed on the metal film. The metal film provided on each of the upper surface 21s1 and the lower surface 21s2 serves to propagate heat, generated by the semiconductor laser element 22 during driving, to the base 10A through the submount 21. As with the support base body 60A of FIGS. 3A and 3B, the submount 21 may, for example, be formed of ceramics, metal materials or metal matrix composite materials described above.

As illustrated in FIG. 6A, the semiconductor laser element 22 is supported by the upper surface 21s1 of the submount 21. The semiconductor laser element 22 has a light emission surface 22e on one of two end surfaces intersecting the Z direction, and emits a laser beam in the +Z direction from the light emission surface 22e. The laser beam diverges at different speeds in the YZ plane and the XZ plane as it travels in the +Z direction. The laser beam diverges relatively fast in the YZ plane and diverges relatively slowly in the XZ plane. When the laser beam is not collimated, the spot of the laser beam has, in the far field, an elliptical shape whose major axis is along the Y direction and whose minor axis is along the X direction in the XY plane.

The semiconductor laser element 22 may emit violet, blue, green, or red laser light in the visible region, or infrared or ultraviolet laser light in the invisible region. The light emission peak wavelength of the violet light is preferably in the range of 400 nm to 420 nm, more preferably in the range of 400 nm to 415 nm. The light emission peak wavelength of the blue light is preferably greater than 420 nm and equal to or less than 495 nm, more preferably in the range of 440 nm to 475 nm.

The light emission peak wavelength of the green light is preferably greater than 495 nm and equal to or less than 570 nm, more preferably in the range of 510 nm to 550 nm. The light emission peak wavelength of the red light is preferably in the range of 605 nm to 750 nm, more preferably in the range of 610 nm to 700 nm.

Examples of the semiconductor laser element 22 that emits the violet light, blue light and green light include laser diodes including nitride semiconductor materials. Examples of the nitride semiconductor materials include GaN, InGaN and AlGaN. Examples of the semiconductor laser element 22 that emits the red light include laser diodes including InAlGaP-based semiconductor materials, GaInP-based semiconductor materials, GaAs-based semiconductor materials and AlGaAs-based semiconductor materials.

As illustrated in FIG. 6A, the lens support member 23 is supported by the upper surface 21s1 of the submount 21. The lens support member 23 includes two columnar portions 23a and a connecting portion 23b that is positioned between the two columnar portions 23a and links the two columnar portions 23a. The two columnar portions 23a are positioned on both sides of the semiconductor laser element 22, and the connecting portion 23b is positioned above the light emission surface 22e of the semiconductor laser element 22. The lens support member 23 supports the fast-axis collimating lens 24 using end surfaces 23as the two columnar portions 23a. The lens support member 23 is positioned, straddling the semiconductor laser element 22, and does not interfere with the laser beam emitted from the semiconductor laser element 22 entering the fast-axis collimating lens 24.

As with the support base 60 of FIGS. 1A and 1B, the lens support member 23 may, for example, be formed of a ceramic described above. As with the condensing lens 70 of FIGS. 1A and 1B, the lens support member 23 may, for example, be formed of a light transmissive material described above. The lens support member 23 may also, for example, be formed of an alloy such as Kovar or CuW, or Si.

As illustrated in FIG. 6A, the fast-axis collimating lens 24 may, for example, be a cylindrical lens having a uniform cross-sectional shape in the X direction. The fast-axis collimating lens 24 has a flat surface on the light incident side and a convex curved surface on the light emission side. The convex curved surface has a curvature in the YZ plane. The focal point of the fast-axis collimating lens 24 substantially coincides with the center of the light emission point of the light emission surface 22e of the semiconductor laser element 22. As illustrated in FIG. 6B, the fast-axis collimating lens 24 collimates, in the YZ plane, a laser beam emitted in the +Z direction from the light emission surface 22e of the semiconductor laser element 22. A region surrounded by a dashed line illustrated in FIG. 6B represents a region in which the intensity of the laser beam is equal to or greater than 1/e² times as great as the peak intensity, where “e” is the base of the natural logarithm. As with the cover 40A of FIGS. 1A and 1B, the fast-axis collimating lens 24 may, for example, be formed of the above light transmissive material.

As illustrated in FIG. 1B, the fast-axis collimating lens 24 is positioned between the mounting surface 10s of the base 10A and the lower surface 44 of the cover 40A, and is positioned on the optical paths of the laser beams L. With the fast-axis collimating lens 24 arranged inside the sealed space formed by the base 10A and the cover 40A, the laser beam L can be collimated before spreading greatly. Therefore, the fast-axis collimating lens 24 can be reduced in size.

Instead of the fast-axis collimating lens 24, a collimating lens may be used that collimates the laser beam L, emitted from the semiconductor laser element 22, not only in the YZ plane but also in the XZ plane. In that case, it is not necessary to provide the slow-axis collimating lens 50 in the light-emitting device 100A. This holds true for the first slow-axis collimating lens array 50a and the second slow-axis collimating lens array 50b in the light-emitting device 100B.

The present disclosure includes a light-emitting device and a light-emitting module described in the following aspects.

### Aspect 1

A Light-emitting Device Comprising:
a base having a mounting surface;
a plurality of semiconductor laser elements each having a light emission surface from which a laser beam is emitted in a first direction, the plurality of semiconductor laser elements arranged on the mounting surface in a second direction intersecting the first direction;
a plurality of first mirror members each having a first reflective surface configured to reflect the laser beam emitted from a corresponding one of the plurality of semiconductor laser elements to change the travel direction of the laser beam into a direction away from the mounting surface;
a cover having a counter surface facing the mounting surface and an upper surface on a side opposite to the counter surface, the cover positioned above the plurality of semiconductor laser elements and the plurality of first mirror members, the cover configured to transmit the laser beams reflected by the first reflective surfaces; and
at least one second mirror member arranged on the upper surface of the cover, and having a second reflective surface configured to reflect the laser beams transmitted through the cover to further change the travel directions of the laser beams,
   wherein
the plurality of first mirror members are arranged on the mounting surface such that positions in the first direction of the first reflective surfaces are different from each other, and
with the the mounting surface serving as a reference plane, heights, from the reference plane, of the optical axes of the laser beams reflected by the second reflective surface are different from each other.

### Aspect 2

The light-emitting device according to aspect 1, wherein
a plurality of distances each defined as a distance between a respective one of the plurality of first mirror members and a corresponding one of the plurality of semiconductor laser elements, are substantially the same.

### Aspect 3

The light-emitting device according to aspect 1 or 2, wherein
the mounting surface on which the plurality of semiconductor laser elements are mounted extends in a single plane.

### Aspect 4

The light-emitting device according to any one of aspects 1 to 3, wherein
the plurality of first mirror members are arranged along the second direction so as to be gradually shifted in the same direction as the first direction or in a direction opposite to the first direction.

### Aspect 5

The light-emitting device according to any one of aspects 1 to 4, further comprising:
a plurality of housings arranged on the mounting surface, wherein
each of the plurality of housings houses a respective one of the plurality of semiconductor laser elements, and a corresponding one of the plurality of first mirror members corresponding to the respective one of the plurality of semiconductor laser elements.

### Aspect 6

The light-emitting device according to any one of aspects 1 to 5, further comprising:
a plurality of fast-axis collimating lenses positioned between the mounting surface of the base and the counter surface of the cover,
   wherein
each of the plurality of fast-axis collimating lenses is configured to collimate, in a fast-axis direction, the laser beam emitted from a corresponding one of the plurality of semiconductor laser elements.

### Aspect 7

The light-emitting device according to any one of aspects 1 to 6, further comprising:
a plurality of slow-axis collimating lenses arranged on the upper surface of the cover,
   wherein
each of the plurality of slow-axis collimating lenses is configured to collimate, in a slow-axis direction, the laser beam emitted from a corresponding one of the plurality of semiconductor laser elements and reflected by the first reflective surface and the second reflective surface sequentially in this order.

### Aspect 8

The light-emitting device according to aspect 7, wherein
the plurality of slow-axis collimating lenses are formed in a monolithic body.

### Aspect 9

The light-emitting device according to any one of aspects 1 to 8, wherein
the base includes a region formed of a material having a thermal conductivity of 10 W/m·K to 2000 W/m·K.

### Aspect 10

The light-emitting device according to any one of aspects 1 to 9, wherein
the plurality of semiconductor laser elements are hermetically sealed by the base and the cover.

### Aspect 11

The light-emitting device according to aspect 3, wherein
the absolute value of a difference in height from the mounting surface between the optical axes of two adjacent ones of a plurality of laser beams that have been emitted from the plurality of semiconductor laser elements and then reflected by the first reflective surfaces and the second reflective surface sequentially in this order is in a range of 0.3 mm to 0.5 mm.

### Aspect 12

A light-emitting device comprising:
a plurality of sub-light-emitting devices each of which is the light-emitting device according to any one of aspects 1 to 11,
   wherein
the plurality of sub-light-emitting devices are arranged in the first direction, and
the plurality of sub-light-emitting devices share the base and the cover.

### Aspect 13

A Light-Emitting Device Comprising:
a base having a mounting surface;
a plurality of first semiconductor laser elements each having a first light emission surface from which a first laser beam is emitted in a first direction, the plurality of first semiconductor laser elements arranged on the mounting surface in a second direction intersecting the first direction;
a plurality of second semiconductor laser elements each having a second light emission surface from which a second laser beam is emitted in the first direction, and arranged on the mounting surface in the second direction;
a plurality of first mirror members each having a first reflective surface configured to reflect the first laser beam emitted from a corresponding one of the plurality of first semiconductor laser elements to change the travel direction of the first laser beam into a direction away from the mounting surface;
a plurality of third mirror members each having a third reflective surface configured to reflect the second laser beam emitted from a corresponding one of the plurality of second semiconductor laser elements to change the travel direction of the second laser beam into a direction away from the mounting surface;
a cover having a counter surface facing the mounting surface and an upper surface on a side opposite to the counter surface, the cover positioned above the plurality of first semiconductor laser elements, the plurality of first mirror members, the plurality of second semiconductor laser elements, and the plurality of third mirror members, the cover configured to transmit the first laser beams reflected by the first reflective surfaces and the second laser beams reflected by the third reflective surfaces;
a second mirror member arranged on the upper surface of the cover, and having a second reflective surface configured to reflect the first laser beams transmitted through the cover to further change the travel directions of the first laser beams; and
a fourth mirror member arranged on the upper surface of the cover, at a location further in a direction opposite to the first direction than the second mirror member, the fourth mirror member having a fourth reflective surface configured to reflect the second laser beams transmitted through the cover to further change the travel directions of the second laser beams,
   wherein
the plurality of second semiconductor laser elements are arranged at a location further in the direction opposite to the first direction than the plurality of first semiconductor laser elements,
the plurality of first mirror members are arranged on the mounting surface such that positions in the first direction of the first reflective surfaces are different from each other,
the plurality of third mirror members are arranged on the mounting surface such that positions in the first direction of the third reflective surfaces are different from each other, and
the plurality of third mirror members are arranged at locations further in the direction opposite to the first direction than the plurality of first mirror members.

### Aspect 14

A light-emitting module comprising:
the light-emitting device according to any one of aspects 1 to 11;
a plurality of fifth mirror members each having a fifth reflective surface configured to reflect, in a third direction, the laser beam emitted from a corresponding one of the semiconductor laser elements and reflected by the first reflective surface and the second reflective surface sequentially in this order; and
a condensing lens configured to couple, to an optical fiber, a plurality of laser beams that have been emitted from the plurality of semiconductor laser elements and then reflected by the first reflective surface, the second reflective surface, and the fifth reflective surface Sequentially in this order.

### Aspect 15

A light-emitting module comprising:
the light-emitting device according to aspect 13;
   a plurality of fifth mirror members each having a fifth reflective surface configured to reflect, in a third direction, the first laser beam emitted from a corresponding one of the first semiconductor laser elements and reflected by the first reflective surface and the second reflective surface sequentially in this order;
a plurality of sixth mirror members each having a sixth reflective surface configured to reflect, in the third direction, the second laser beam emitted from a corresponding one of the second semiconductor laser elements and reflected by the third reflective surface and the fourth reflective surface sequentially in this order; and
a condensing lens configured to couple, to an optical fiber, a plurality of first laser beams that have been emitted from the plurality of first semiconductor laser elements and then reflected by the first reflective surface, the second reflective surface, and the fifth reflective surface sequentially in this order, and a plurality of second laser beams that have been emitted from the plurality of second semiconductor laser elements and then reflected by the third reflective surface, the fourth reflective surface, and the sixth reflective surface sequentially in this order.

### Aspect 16

The light-emitting module according to aspect 15, wherein
the second laser beam emitted from each of the plurality of second semiconductor laser elements has the same polarization direction as that of the first laser beam emitted from each of the plurality of first semiconductor laser elements, and
the light-emitting module further comprises:
   a half-wave plate arranged on optical paths of the plurality of first laser beams or optical paths of the plurality of second laser beams; and
   a polarizing beam splitter configured to direct the plurality of first laser beams that have been transmitted through the half-wave plate and the plurality of second laser beams that have not been transmitted through the half-wave plate toward the condensing lens, or direct the plurality of second laser beams that have been transmitted through the half-wave plate and the plurality of first laser beams that have not been transmitted through the half-wave plate toward the condensing lens.

The light-emitting device and light-emitting module according to the present disclosure may, particularly, be employed to provide a high-power laser beam by combining a plurality of laser beams. In addition, the light-emitting device and light-emitting module according to the present disclosure may, for example, be useful, in industrial fields requiring high-power laser beam sources, for cutting, drilling, local heat treatment, surface treatment, metal welding, and 3D printing of various materials, for example.

### REFERENCE CHARACTER LIST

10A, 10B: Base 10h: Housing 10s: Mounting surface 12a: First upper surface 12b: Second upper surface 14: Lower surface 16: Bonding region 20: Laser beam source 20a: First laser beam source 20b: Second laser beam source 21: Submount 21s1: Upper surface 21s2: Lower surface 22: Semiconductor laser element 22e: Light emission surface 23: Lens support member 23a: Columnar portion 23as: End surface 23b: Linking portion 24: Fast-axis collimating lens 30a: First mirror member 30as: First reflective surface 30b: Second mirror member 30bs: Second reflective surface 30c: Third mirror member 30cs: Third reflective surface 30d: Fourth mirror member 30ds: Fourth reflective surface 32: Resin layer 32a: First resin layer 32b: Second resin layer 34a: First support member 34b: Second support member 40A, 40B: Cover 42: Upper surface 44: Lower surface 46: Light transmission portion 46a: First light transmission portion 46b: Second light transmission portion 48: Light-blocking film 50: Slow-axis collimating lens array 50s: Slow-axis collimating lens 50a: First slow-axis collimating lens array 50as: First slow-axis collimating lens 50b: Second slow-axis collimating lens array 50bs: Second slow-axis collimating lens 60A, 60B: Support base body 60A1, 60B1: First portion 60A2, 60B2: Second portion 60A3, 60B3: Third portion 60s1: First mounting surface 60s2: Second mounting surface 60s3: Third mounting surface 70: Condensing lens 70a: Fast-axis condensing lens 70b: Slow-axis condensing lens 80: Optical fiber 80a: Light incident end 80b: Light emission end 82: Support member 90, 90a, 90b, 90c: Mirror member 90s, 90as, 90bs, 90cs: Reflective surface 92: Half-wave plate 94: Optical element 96: Polarizing beam splitter 100A, 110A, 120A, 100B: Light-emitting device 200A, 200B: Light-emitting module L: laser beams La: First laser beam Lb: Second laser beam Ref: Reference plane

1. A light-emitting device comprising:
a base having a mounting surface;
a plurality of semiconductor laser elements each having a light emission surface and being configured to emit a laser beam from the light emission surface in a first direction, the plurality of semiconductor laser elements arranged on the mounting surface in a second direction intersecting the first direction;
a plurality of first mirror members each having a first reflective surface configured to reflect the laser beam emitted from a corresponding one of the plurality of semiconductor laser elements to change a travel direction of the laser beam into a direction away from the mounting surface;
a cover having a lower surface facing the mounting surface and an upper surface on a side opposite to the lower surface, the cover positioned above the plurality of semiconductor laser elements and the plurality of first mirror members, the cover configured to transmit the laser beams reflected by the first reflective surfaces; and
at least one second mirror member arranged on the upper surface of the cover, and having a second reflective surface configured to reflect the laser beams transmitted through the cover to further change the travel directions of the laser beams, wherein:
the plurality of first mirror members are arranged on the mounting surface such that positions in the first direction of the first reflective surfaces are different from each other, and
with the mounting surface serving as a reference plane, heights, from the reference plane, of optical axes of the laser beams reflected by the second reflective surface are different from each other.

2. The light-emitting device according to claim 1, wherein:
a plurality of distances, each defined as a distance between a respective one of the plurality of first mirror members and a corresponding one of the plurality of semiconductor laser elements, are substantially the same.

3. The light-emitting device according to claim 1, wherein:
the mounting surface on which the plurality of semiconductor laser elements are mounted extends in a single plane.

4. The light-emitting device according to claim 1, wherein:
the plurality of first mirror members are arranged along the second direction so as to be gradually shifted in the first direction or in a direction opposite to the first direction.

5. The light-emitting device according to claim 2, further comprising:
a plurality of housings arranged on the mounting surface, wherein:
each of the plurality of housings houses a respective one of the plurality of semiconductor laser elements, and a corresponding one of the plurality of first mirror members corresponding to the respective one of the plurality of semiconductor laser elements.

6. The light-emitting device according to claim 1, further comprising:
a plurality of fast-axis collimating lenses positioned between the mounting surface of the base and the lower surface of the cover, wherein:
each of the plurality of fast-axis collimating lenses is configured to collimate, in a fast-axis direction, the laser beam emitted from a corresponding one of the plurality of semiconductor laser elements.

7. The light-emitting device according to claim 1, further comprising:
a plurality of slow-axis collimating lenses arranged on the upper surface of the cover, wherein:
each of the plurality of slow-axis collimating lenses is configured to collimate, in a slow-axis direction, the laser beam emitted from a corresponding one of the plurality of semiconductor laser elements and reflected by the first reflective surface and the second reflective surface sequentially in this order.

8. The light-emitting device according to claim 7, wherein:
the plurality of slow-axis collimating lenses are formed in a monolithic body.

9. The light-emitting device according to claim 1, wherein:
the base includes a region formed of a material having a thermal conductivity of 10 W/m·K to 2000 W/m·K.

10. The light-emitting device according to claim 1, wherein:
the plurality of semiconductor laser elements are hermetically sealed by the base and the cover.

11. The light-emitting device according to claim 1, wherein:
the absolute value of a difference in height from the mounting surface between the optical axes of two adjacent ones of a plurality of laser beams that have been emitted from the plurality of semiconductor laser elements and then reflected by the first reflective surfaces and the second reflective surface sequentially in this order is in a range of 0.3 mm to 0.5 mm.

12. A light-emitting device comprising:
a plurality of sub-light-emitting devices each of which is the light-emitting device according to claim 1, wherein:
the plurality of sub-light-emitting devices are arranged in the first direction, and
the plurality of sub-light-emitting devices share the base and the cover.

13. A light-emitting device comprising:
a base having a mounting surface;
a plurality of first semiconductor laser elements each having a first light emission surface and being configured to emit a laser beam from the light emission surface in a first direction, the plurality of first semiconductor laser elements arranged on the mounting surface in a second direction intersecting the first direction;
a plurality of second semiconductor laser elements each having a second light emission surface and being configured to emit a second laser beam from the light emission surface in the first direction, and arranged on the mounting surface in the second direction;
a plurality of first mirror members each having a first reflective surface configured to reflect the first laser beam emitted from a corresponding one of the plurality of first semiconductor laser elements to change a travel direction of the first laser beam into a direction away from the mounting surface;
a plurality of third mirror members each having a third reflective surface configured to reflect the second laser beam emitted from a corresponding one of the plurality of second semiconductor laser elements to change a travel direction of the second laser beam into a direction away from the mounting surface;
a cover having a lower surface facing the mounting surface and an upper surface on a side opposite to the lower surface, the cover positioned above the plurality of first semiconductor laser elements, the plurality of first mirror members, the plurality of second semiconductor laser elements, and the plurality of third mirror members, the cover configured to transmit the first laser beams reflected by the first reflective surfaces and the second laser beams reflected by the third reflective surfaces;
a second mirror member arranged on the upper surface of the cover, and having a second reflective surface configured to reflect the first laser beams transmitted through the cover to further change the travel directions of the first laser beams; and
a fourth mirror member arranged on the upper surface of the cover, at a location further in a direction opposite to the first direction than the second mirror member, the fourth mirror member having a fourth reflective surface configured to reflect the second laser beams transmitted through the cover to further change the travel directions of the second laser beams, wherein:
the plurality of second semiconductor laser elements are arranged at a location further in the direction opposite to the first direction than the plurality of first semiconductor laser elements,
the plurality of first mirror members are arranged on the mounting surface such that positions in the first direction of the first reflective surfaces are different from each other,
the plurality of third mirror members are arranged on the mounting surface such that positions in the first direction of the third reflective surfaces are different from each other, and
the plurality of third mirror members are arranged at locations further in the direction opposite to the first direction than the plurality of first mirror members.

14. A light-emitting module comprising:
the light-emitting device according to claim 1;
a plurality of fifth mirror members each having a fifth reflective surface configured to reflect, in a third direction, the laser beam emitted from a corresponding one of the semiconductor laser elements and reflected by the first reflective surface and the second reflective surface sequentially in this order; and
a condensing lens configured to couple, to an optical fiber, a plurality of laser beams that have been emitted from the plurality of semiconductor laser elements and then reflected by the first reflective surface, the second reflective surface, and the fifth reflective surface sequentially in this order.

15. A light-emitting module comprising:
the light-emitting device according to claim 13;
a plurality of fifth mirror members each having a fifth reflective surface configured to reflect, in a third direction, the first laser beam emitted from a corresponding one of the first semiconductor laser elements and reflected by the first reflective surface and the second reflective surface sequentially in this order;
a plurality of sixth mirror members each having a sixth reflective surface configured to reflect, in the third direction, the second laser beam emitted from a corresponding one of the second semiconductor laser elements and reflected by the third reflective surface and the fourth reflective surface sequentially in this order; and
a condensing lens configured to couple, to an optical fiber, a plurality of first laser beams that have been emitted from the plurality of first semiconductor laser elements and then reflected by the first reflective surface, the second reflective surface, and the fifth reflective surface sequentially in this order, and a plurality of second laser beams that have been emitted from the plurality of second semiconductor laser elements and then reflected by the third reflective surface, the fourth reflective surface, and the sixth reflective surface sequentially in this order.

16. The light-emitting module according to claim 15, wherein:
the second laser beam emitted from each of the plurality of second semiconductor laser elements has the same polarization direction as that of the first laser beam emitted from each of the plurality of first semiconductor laser elements, and
the light-emitting module further comprises:
a half-wave plate arranged on optical paths of the plurality of first laser beams or optical paths of the plurality of second laser beams; and
a polarizing beam splitter configured to direct the plurality of first laser beams that have been transmitted through the half-wave plate and the plurality of second laser beams that have not been transmitted through the half-wave plate toward the condensing lens, or direct the plurality of second laser beams that have been transmitted through the half-wave plate and the plurality of first laser beams that have not been transmitted through the half-wave plate toward the condensing lens.
